(19) United States
(12) Patent Application Publication
(10) Pub. No.: US 2023/0081984 A1
(43) Pub. Date: Mar. 16, 2023

(54) FOLDABLE ELECTRONIC DEVICE INCLUDING FLEXIBLE PRINTED CIRCUIT BOARD

(71) Applicant: Samsung Electronics Co., Ltd., Suwon-si (KR)

(72) Inventors: Sangkyun LEE, Suwon-si (KR); Kwangeun GO, Suwon-si (KR); Kwangmin GIL, Suwon-si (KR); Yongyoun KIM, Suwon-si (KR)

(21) Appl. No.: 17/962,105

(22) Filed: Oct. 7, 2022

Related U.S. Application Data
(63) Continuation of application No. PCT/KR2022/013789, filed on Sep. 15, 2022.

(30) Foreign Application Priority Data
Sep. 15, 2021 (KR) 10-2021-0123446

(51) Int. Cl. H05K 5/02; H04M 1/02

(52) U.S. Cl. CPC H05K 5/0226; H04M 1/0216

(57) ABSTRACT

An electronic device is provided. The electronic device includes a foldable housing and a flexible printed circuit board. The foldable housing includes a first housing, a second housing, and a folding part between the first housing and the second housing. The flexible printed circuit board may be located in an inner space of the foldable housing. The flexible printed circuit board includes a first part corresponding to the folding part, a second part extending from the first part to the first housing, and a third part extending from the first part to the second housing. The folding part includes at least one hinge connecting the first housing and the second housing with each other, and a hinge housing configured to cover the at least one hinge. The hinge housing includes a first surface exposing to an outside in a folding state of the foldable housing.

### CROSS-REFERENCE TO RELATED APPLICATION(S)

This application is a continuation application, claiming priority under § 365(c), of an International application No. PCT/KR2022/013789, filed on Sep. 15, 2022, which is based on and claims the benefit of a Korean patent application number 10-2021-0123446, filed on Sep. 15, 2021, in the Korean Intellectual Property Office, the disclosure of which is incorporated by reference herein in its entirety.

### TECHNICAL FIELD

The disclosure relates to a foldable electronic device including a flexible printed circuit board (FPCB).

### BACKGROUND ART

A foldable electronic device may include a flexible printed circuit board (FPCB) located in an inner space of the foldable electronic device across a folding part. The flexible printed circuit board may be deformed corresponding to folding or unfolding of the foldable electronic device.

The above information is presented as background information only to assist with an understanding of the disclosure. No determination has been made, and no assertion is made, as to whether any of the above might be applicable as prior art with regard to the disclosure.

### DISCLOSURE OF INVENTION

### Technical Problem

A stress (e.g., bending stress) occurring in a flexible printed circuit board that is deformed during folding or unfolding of a foldable electronic device may exert an influence on the damage of the flexible printed circuit board.

Aspects of the disclosure are to address at least the above-mentioned problems and/or disadvantages and to provide at least the advantages described below. Accordingly, an aspect of the disclosure is to provide a foldable electronic device including a flexible printed circuit board, which can reduce the damage of the flexible printed circuit board that is deformed during folding or unfolding of the foldable electronic device.

Additional aspects will be set forth in part in the description which follows and, in part, will be apparent from the description, or may be learned by practice of the presented embodiments.

### Solution to Problem

In accordance with an aspect of the disclosure, an electronic device is provided. The electronic device includes a foldable housing and a flexible printed circuit board. The foldable housing includes a first housing, a second housing, and a folding part between the first housing and the second housing. The flexible printed circuit board may be located in an inner space of the foldable housing. The flexible printed circuit board includes a first part corresponding to the folding part, a second part extending from the first part to the first housing, and a third part extending from the first part to the second housing. The folding part includes at least one hinge connecting the first housing and the second housing with each other, and a hinge housing configured to cover the at least one hinge. The hinge housing includes a first surface exposing to an outside in a folding state of the foldable housing and forming a part of an outer surface of the electronic device, and a second surface located on an opposite side to the first surface and formed with a recess corresponding to the first part. As seen from a cross section of a plane that is vertical to a direction of a folding axis of the folding part, an area forming the recess on the second surface includes a first area aligned with the folding axis and protruding in a first direction toward the folding axis, a second area extending from one end part of the first area, and a third area extending from the other end part of the first area and located on an opposite side to the second area across the first area. Based on a center axis that is vertical to the folding axis and passes the folding axis, the recess includes a first concave part formed on a part of the first area and the second area and carved in a second direction that is opposite to the first direction, and a second concave part formed on a part of the first area and the third area and carved in the second direction.

### Advantageous Effects of Invention

The foldable electronic device including the flexible printed circuit board according to an embodiment of the disclosure can reduce the damage or permanent deformation of the flexible printed circuit board by reducing the stress (e.g., bending stress) occurring in the flexible printed circuit board that is deformed when the foldable electronic device is folded or unfolded.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is diagrams illustrating an electronic device in an unfolding state according to an embodiment of the disclosure;

FIG. 2 is diagrams illustrating an electronic device in a folding state according to an embodiment of the disclosure;

FIG. 3 is an exploded perspective view of a part of an electronic device according to an embodiment of the disclosure;

FIG. 4 is a diagram illustrating a part of an electronic device according to an embodiment of the disclosure;

FIG. 5 is a cross-sectional view illustrating a part of an electronic device, being cut along line C-C′ of FIG. 1 according to an embodiment of the disclosure;

FIG. 6 is a cross-sectional view illustrating a part of an electronic device, being cut along line D-D′ of FIG. 2 according to an embodiment of the disclosure;

FIG. 7 is an enlarged view illustrating a part of the cross-sectional view of FIG. 5 according to an embodiment of the disclosure; and

FIG. 8 is a cross-sectional view illustrating a part of an electronic device in a state where an electronic device according to a second comparative example, being provided with, for example, a hinge housing having a recess that does not include a first area according to an embodiment of the disclosure.

Throughout the drawings, it should be noted that like reference numbers are used to depict the same or similar elements, features, and structures.

### MODE FOR THE INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In the disclosure, phrases, such as “A or B”, “at least one of A and B”, “at least one of “A or B”, “A, B, or C”, “at least one of A, B, and C”, and “at least one of A, B, or C”, may include any one of the items enumerated with the corresponding phrase of the phrases or all possible combinations thereof. The terms, such as “1^{st}”, “2^{nd}” or “first” or “second”, may be used to simply distinguish the corresponding constituent element from another corresponding constituent element, and may not limit the corresponding constituent element from the other side (e.g., importance or order).

An electronic device according to various embodiments disclosed in the disclosure may be a device of various forms. For example, the electronic device may include a portable communication device (e.g., smart phone), a computer device, a portable multimedia device, a portable medical device, a camera, a wearable device, or a home appliance. The electronic device according to an embodiment of the disclosure is not limited to the above-described devices.

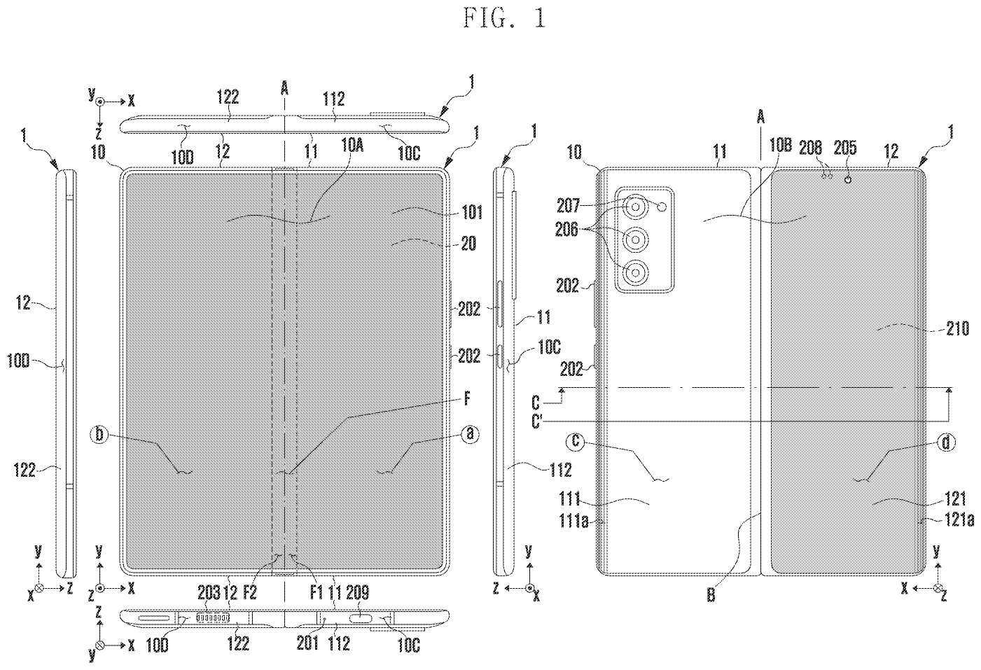

FIG. 1 is diagrams illustrating an electronic device 1 in a flat or unfolding state (or unfolding state) according to an embodiment of the disclosure.

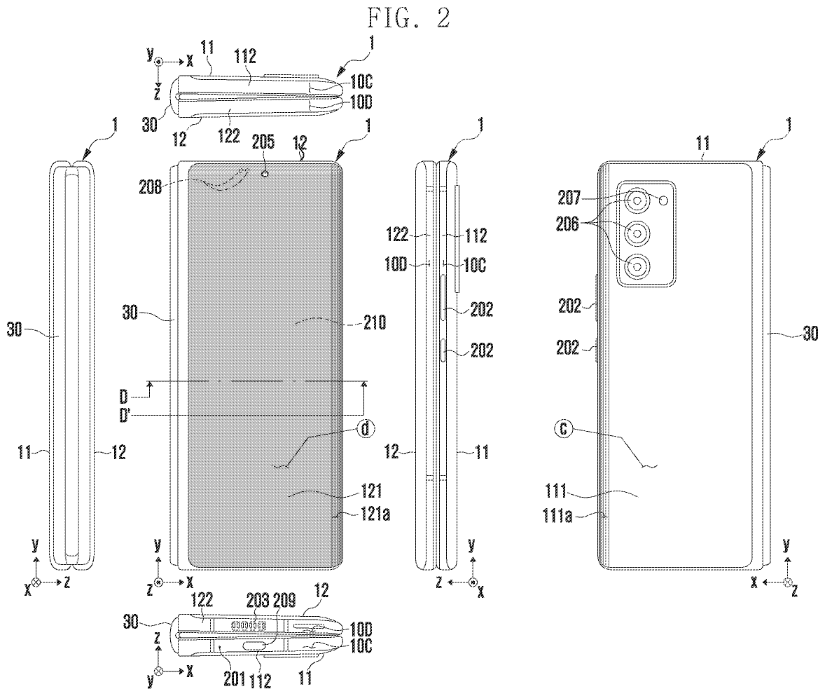

FIG. 2 is diagrams illustrating an electronic device 1 in a folding state (or folding state) according to an embodiment of the disclosure.

Referring to FIGS. 1 and 2, in an embodiment, the electronic device 1 may include a foldable housing 10 and a flexible display 20. The foldable housing 10 may include a front surface 10A of the electronic device 1, and a rear surface 10B of the electronic device 1 located on an opposite side of the front surface 10A. To help understanding, it is interpreted that the front surface 10A of the electronic device 1 is a surface from which the flexible display 20 is exposed to outside, and the rear surface 10B of the electronic device 1 is a surface located on an opposite side of the front surface 10A. The foldable housing 10 may include a first side surface 10C and a second side surface 10D of the electronic device 1, which surround at least a part of a space between the front surface 10A and the rear surface 10B. The front surface 10A may include a first cover area \textcircled{a}, a second cover area \textcircled{b}, and a folding cover area F between the first cover area \textcircled{a} and the second cover area \textcircled{b}. In a state where the foldable housing 10 is unfolded, the front surface 10A may substantially be a plane, and the first cover area \textcircled{a}, the second cover area \textcircled{b}, and the folding cover area F may be directed substantially in the same direction. The rear surface 10B may include a third cover area \textcircled{c} and a fourth cover area \textcircled{d}. The third cover area \textcircled{c} may be located on an opposite side to the first cover area \textcircled{a}, and may be directed in an opposite direction to the direction of the first cover area \textcircled{a}. The fourth cover area \textcircled{d} may be located on an opposite side to the second cover area \textcircled{b} of the front surface 10A, and may be directed in an opposite direction to the second cover area \textcircled{b}. In an embodiment, the foldable housing 10 may be implemented in an in-folding structure in which the front surface 10A is folded inwardly. For example, in a folding state (refer to FIG. 1) of the foldable housing 10, the folding cover area F may be disposed in the form of a plane, and the first cover area \textcircled{a} and the second cover area \textcircled{b} may form an angle of about 180 degrees. In the folding state (refer to FIG. 2) of the foldable housing 10, the folding cover area F may be disposed in the form of a curved surface, and the first cover area \textcircled{a} and the second cover area \textcircled{b} may form an angle that is different from the angle of about 180 degrees. The folding state may include a fully folding state or a middle state. The fully folding state (refer to FIG. 2) may be a maximally folding state where the first cover area \textcircled{a} and the second cover area \textcircled{b} are no longer getting closer to each other, and for example, the first cover area \textcircled{a} and the second cover area \textcircled{b} may form an angle of about 0 degree to about 10 degrees. In the fully folding state, the front surface 10A may not substantially be exposed to the outside. The middle state may indicate a state between the unfolding state and the fully folding state. The folding cover area F of the front surface 10A may be further bent in the fully folding state rather than the middle state. In a certain embodiment, the electronic device 1 may be implemented in an out-folding structure in which the front surface 10A (or screen) is folded outside.

According to an embodiment, the foldable housing 10 may include a front cover (e.g., window) 101 that provides the front surface 10A at least partly. The flexible display 20 may overlap the front cover 101 at least partly, and may be located in an inner space of the electronic device 1. The front cover 101 may protect the flexible display 20 from outside, and may be substantially transparent. Light output from the flexible display 20 may propagate to the outside after passing through the front cover 101. For example, the flexible display 20 may include a first display area (or first active area) that overlaps the first cover area \textcircled{a}, a second display area (or second active area) that overlaps the second cover area \textcircled{b}, and a third display area (or third active area) that overlaps the folding cover area F. In a certain embodiment, the third display area may be referred to as other various terms, such as “folding display area” or “bendable display area”. A screen may indicate an area on which an image can be expressed in a device including the flexible display 20 and the front cover 101, and for example, may include the display area of the flexible display 20 and an area of the front cover 101 that overlaps the display area. In a certain embodiment, the front cover 101 is a constituent element included in the flexible display 20, and may be integrally formed with the flexible display 20. The front cover 101 may be implemented in the form of a thin film, such as a film, that has flexibility. For example, the front cover 101 may include a plastic film (e.g., polyimide film) or a thin film glass (e.g., ultra-thin glass (UTG)). In a certain embodiment, the front cover 101 may include a plurality of layers. For example, the front cover 101 may be in the form in which a coated layer or a protection layer of various polymer materials (e.g., polyester (PET), polyimide (PI), or thermoplastic polyurethane (TPU)) is disposed on the plastic film or the thin film glass.

According to an embodiment, the foldable housing 10 may include a first housing (or a first housing part or a first housing structure) 11, a second housing (or a second housing part or a second housing structure) 12, and a folding part between the first housing 11 and the second housing 12. Coordinate axes illustrated to help understanding are based on the first housing 11, and for example, the first cover area \textcircled{a} may be substantially directed in a +z-axis direction, and the third cover area \textcircled{c} may be substantially in a −z-axis direction. The first housing 11 and the second housing 12 may be connected to the folding part, and may be mutually rotatable based on a folding axis A of the foldable housing 10. The folding part may include, for example, a hinge assembly (or a hinge structure) (not illustrated). The folding axis A may be a rotation axis of the hinge assembly. In an illustrated example, the folding axis A may be parallel to a y-axis direction. The first housing 11 may include a first cover part of the front cover 101 located on one side based on the folding axis A, a first rear cover 111 that provides at least a part of the third cover area \textcircled{c} of the rear surface 10B, and a first side member (or a first side bezel structure) 112 which surrounds at least a part of the space between the first cover part and the first rear cover 111, and provides a first side surface 10C. The first cover part of the front cover 101 may provide, for example, the first cover area \textcircled{a} and a first folding cover area F1 located on one side based on the folding axis A in the folding cover area F. The second housing 12 may include a second cover part of the front cover 101 located on one side based on the folding axis A, a second rear cover 121 that provides at least a part of the fourth cover area \textcircled{d} of the rear surface 10B, and a second side member (or a side bezel structure) 222 which surrounds at least a part of the space between the second cover part and the second rear cover 121, and provides a second side surface 10D. The second cover part of the front cover 101 may provide, for example, a second cover area \textcircled{b}, and a second folding cover area F2 located on the other side based on the folding axis A in the folding cover area 101. In the fully folding state of the foldable housing 10, the first side member 112 and the second side member 122 may be aligned to at least partly overlap each other. The first side member 112 and/or the second side member 122 may be formed of ceramic, polymer, metal (e.g., aluminum, stainless steel, or magnesium) or a combination of at least two of the above materials. The first side member 112 and/or the second side member 122 may include, for example, various metal materials, such as titanium, an amorphous alloy, a metal-ceramic composite material (e.g., cermet), stainless steel, magnesium, a magnesium alloy, aluminum, an aluminum alloy, a zinc alloy, or a copper alloy. The first rear cover 111 and/or the second rear cover 121 may be substantially opaque. For example, the first rear cover 111 and/or the second rear cover 121 may be formed of coated or colored glass, ceramic, polymer, metal (e.g., aluminum, stainless steel, or magnesium), or a combination of at least two of the above materials. For example, the first rear cover 111 or the second rear cover 121 may include at least one coated layer disposed on a plate using the plate and coatings of various materials, such as transparent glass, ceramic, or polymer. As another example, the first rear cover 111 or the second rear cover 121 may include the plate of various materials, such as transparent glass, ceramic, or polymer, and a film (e.g., decoration film) attached to the plate and having various visual effects. In a certain embodiment, the first rear cover 111 and the first side member 112 may be integrally formed, and may include the same material. In a certain embodiment, the second rear cover 121 and the second side member 122 may be integrally formed, and may include the same material.

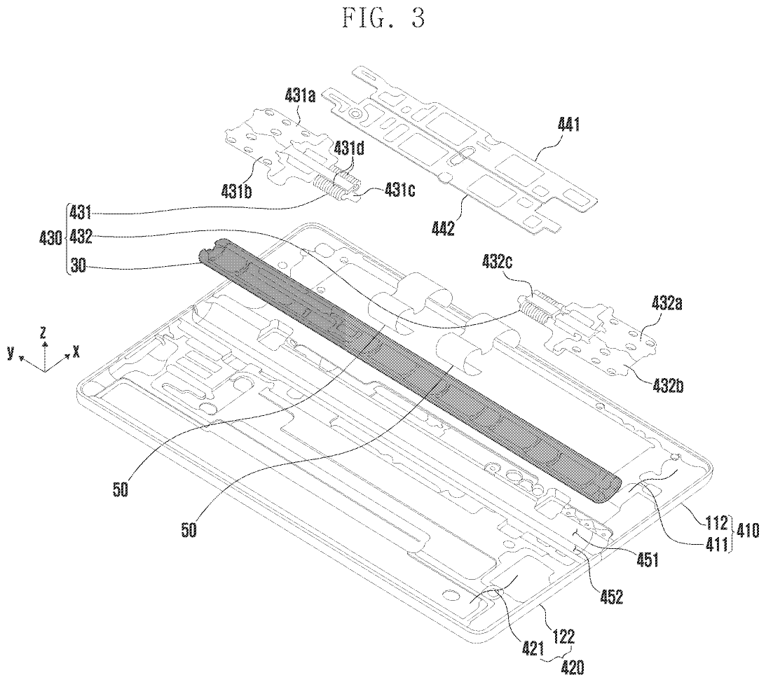

According to an embodiment, the folding part may include a hinge housing 30. The hinge housing 30 may cover at least one hinge connecting the first housing 11 and the second housing 12 with each other. In a certain embodiment, the hinge housing 30 may be referred to as a “hinge cover”. In case that the electronic device 1 switched from an unfolding state of FIG. 1 to a folding state of FIG. 2, the hinge housing 30 can cover the exposure of an inside of the electronic device 1 as the gap B between the first housing 11 and the second housing 12 is opened. As illustrated in FIG. 1, in the unfolding state of the electronic device 1, the gap B may not substantially exist, and the hinge housing 30 may not be exposed to the outside through being hidden by the first housing 11 and the second housing 12. Although not illustrated, in the middle state of the electronic device 1, the hinge housing 30 may be partly exposed between the first housing 11 and the second housing 12. The hinge housing 30 may be more exposed in the folding state of FIG. 3 rather than in the middle state of the electronic device 1.

According to various embodiments, the foldable housing 10 may be referred to as a structure (e.g., foldable housing structure or foldable housing assembly) that provides at least a part of the front surface 10A, the rear surface 10B, the first side surface 10C, and the second side surface 10D. For example, the foldable housing 10 may include a first housing part, a second housing part, and a folding part connected to the first housing part and the second housing part. The folding part may indicate a more flexible part than the first housing part and the second housing part, and may be bent in the folding state of the electronic device 1. The folding part may include, for example, a hinge assembly. As another example, the folding part may include a structure in which a plurality of bars are arranged (e.g., multi-bar structure). However, the structure of the folding part is not limited thereto, but may be implemented as other various structures having bending characteristics while connecting the first housing and the second housing with each other.

According to an embodiment, the electronic device 1 may include a display (hereinafter, sub-display) 210 located inside the first housing, being adjacent to the first rear cover 111. A partial area of the first rear cover 111 may overlap the sub-display 210, and may be substantially transparent. The electronic device 1 may output an image using the sub-display 210 instead of the flexible display 20 in the folding state of FIG. 2.

According to an embodiment, the second rear cover 121 may include a second curved surface area 121a being bent from the fourth cover area \textcircled{d} to the second cover area \textcircled{b} and extending seamlessly. The second curved surface area 121a may be provided adjacent to a long edge of the second rear cover 121 that is substantially parallel to the folding axis A. The sub-display 210 may include a flexible display that can be disposed in a corresponding form.

According to an embodiment, the first rear cover 111 may include a first curved surface area 111a being bent from the third cover area \textcircled{c} to the first cover area A and extending seamlessly. The first curved surface area 111a may be provided adjacent to a long edge of the first rear cover 111 that is substantially parallel to the folding axis A. For example, in the unfolding state (refer to FIG. 1) or the folding state (refer to FIG. 2) of the electronic device 1, for aesthetic, the first curved surface area 111a and the second curved surface area 121a may be located substantially symmetrically on opposite sides to each other. In a certain embodiment, the first curved surface area 111a or the second curved surface area 121a may be omitted.

According to an embodiment, the electronic device may include an input module, a sound output module, a camera module, a sensor module, or a connection terminal. In a certain embodiment, the electronic device 1 may omit at least one of the constituent elements, or may additionally include other constituent elements. The location or the number of constituent elements included in the electronic device 1 is not limited to the illustrated example, but may vary.

The input module may include, for example, a microphone located inside the electronic device 1 and a microphone hole 201 provided on the first side surface 10C to correspond to the microphone. The location or the number of input modules including the microphone and the corresponding microphone hole 201 is not limited to the illustrated example, but may vary. In a certain embodiment, the electronic device 1 may include a plurality of microphones that can detect the direction of sound.

The input module may include, for example, key input devices 202. The key input devices 202 may be located, for example, in an opening (not illustrated) provided on the first side surface 10C. In a certain embodiment, the electronic device 1 may not include some or all of the key input devices 202, and the key input devices not included may be included as soft keys using the flexible display 20 or the sub-display 210. In a certain embodiment, the input module may include at least one sensor module.

The sound output module may include, for example, a speaker located inside the electronic device 1 and a speaker hole 203 provided on the second side surface 10D to correspond to the speaker. The location or the number of sound output modules including speakers and corresponding speaker holes 203 is not limited to the illustrated example, but may vary. In a certain embodiment, the microphone hole 201 and the speaker hole 203 may be implemented as one hole. In a certain embodiment, a piezo-electric speaker of which the speaker hole 203 is omitted may be implemented. The sound output module may include, for example, a call receiver located inside the electronic device 1 and a receiver hole (not illustrated) provided on the fourth cover area \textcircled{d} to correspond to the call receiver.

The camera module may include, for example, a first camera module (or front camera module) 205 located to correspond to the fourth cover area \textcircled{d}, or a plurality of second camera modules (or rear camera modules) 206 located to correspond to the third cover area \textcircled{c}. Each of the first camera module 205 and/or the plurality of second camera module 206 may include one or a plurality of lenses, an image sensor, and/or an image signal processor. The location or the number of the first camera module 205 or the plurality of second camera modules is not limited to the illustrated example, but may vary.

According to an embodiment, the sub-display 210 may include an opening aligned with the first camera module 205. External light may arrive at the first camera module 205 after passing through the second rear cover 121 and the opening of the sub-display 210. In a certain embodiment, the opening of the sub-display 210 may be provided in the form of a notch in accordance with the location of the first camera module 205. In a certain embodiment, the first camera module 205 may be located on the rear surface of the sub-display 210 or below (or beneath) the sub-display 210, and a related function (e.g., image capturing) may be performed without visually distinguishing (or exposing) the location of the first camera module 205. For example, the first camera module 205 may Include a hidden display rear camera (e.g., under display camera (UDC)). In a certain embodiment, the first camera module 205 may be located to be aligned with a recess provided on the rear surface of the sub-display 210. The first camera module 205 may obtain an image of an external subject in a state where it is disposed to overlap at least a part of the screen without being visually exposed to the outside. In this case, a partial area of the sub-display 210 that is at least partly overlap the first camera module 205 may include other pixel structure and/or wiring structure in contrast to other areas. For example, the partial area of the sub-display 210 that is at least partly overlap the first camera module 205 may include a different pixel density in contrast to other areas. The pixel structure and/or the wiring structure provided on the partial area of the sub-display 210 that is at least partly overlap the first camera module 205 may reduce a loss of light between the outside and the first camera module 205. In a certain embodiment, a pixel may not be disposed on the partial area of the sub-display 210 that is at least partly overlap the first camera module 205.

According to an embodiment, the plurality of second camera modules 206 may have different attributes (e.g., viewing angles) or functions, and for example, may include a dual camera or a triple camera. The plurality of second camera modules 206 may include a plurality of camera modules including lenses having different viewing angles, and based on a user selection, the electronic device 1 may control to change the viewing angle of the camera module being performed in the electronic device 1. The plurality of second camera modules 206 may include at least one of a wide-angle camera, a telephoto camera, a color camera, a monochrome camera, or an infrared (IR) camera (e.g., time of flight (TOF) camera or structured light camera). In a certain embodiment, the IR camera may operate as at least a part of the sensor module. The electronic device 1 may include a flash 207 as a light source for the plurality of second camera modules 206. The flash 207 may include, for example, a light-emitting diode or a xenon lamp.

The sensor module may generate an electrical signal or a data value corresponding to an operation state inside the electronic device 1 or an external environment state. The sensor module may include, for example, at least one of a proximity sensor, a gesture sensor, a color sensor, an infrared (IR) sensor, a biosensor (e.g., fingerprint sensor or a heart rate monitor (HRM) sensor), a temperature sensor, a humidity sensor, or an illumination sensor.

According to an embodiment, the sensor module may include an optical sensor 208 located inside the electronic device 1 to correspond to the fourth cover area \textcircled{d}. The optical sensor 208 may include, for example, the proximity sensor or the illumination sensor. The optical sensor 208 may be aligned with the opening provided on the sub-display 210. The external light may arrive at the optical sensor 208 after passing through the second rear cover 121 and the opening of the sub-display 210. In a certain embodiment, the optical sensor 208 may be located on the rear surface of the sub-display 210 or below (or beneath) the sub-display 210, and a related function may be performed without visually distinguishing (or exposing) the location of the optical sensor 208. In a certain embodiment, the optical sensor 208 may be located to be aligned with the recess provided on the rear surface of the sub-display 210. The optical sensor 208 may perform a sensing function in a state where it is disposed to overlap at least a part of the screen without being visually exposed to the outside. In this case, a partial area of the sub-display 210 that is at least partly overlap the optical sensor 208 may include a different pixel structure and/or wiring structure in contrast to other areas. For example, the partial area of the sub-display 210 that is at least partly overlap the optical sensor 208 may have a different pixel density in contrast to other areas. In a certain embodiment, the sensor module may include a fingerprint sensor (not illustrated) located under the sub-display 210. The fingerprint sensor may be implemented by a capacitive method, an optical method, or an ultrasonic method. The pixel structure and/or the wiring structure provided on the partial area of the sub-display 210 that is at least partly overlap the sensor module may reduce a loss of light while various types of signals (e.g., optical or ultrasonic signals) related to the sensor module pass between the outside and the sensor module. In a certain embodiment, a plurality of pixels may not be disposed on the partial area of the sub-display 210 that is at least partly overlap the sensor module.

The connection terminal may include, for example, a connector (e.g., USB connector) located inside the electronic device 1. The electronic device may include a connector hole 209 provided on the first side surface 10C to correspond to the connector. The electronic device 1 may transmit and/or receive a power and/or data with an external electronic device electrically connected to the connector through the connector hole 209. The location or the number of connectors and corresponding connector holes 209 are not limited to the illustrated example, but may vary.

According to various embodiments, the electronic device 1 may include a detachable pen input device (e.g., an electronic pen, a digital pen, or a stylus pen) (not illustrated). For example, the pen input device may be detachably attached to the hinge housing 30. The hinge housing 40 may include a recess, and the pen input device may be fitted into the recess. The pen input device may be detachably attached to the recess of the hinge housing 30 exposed to the outside in the folding state (refer to FIG. 2) or the middle state of the electronic device 1. In a certain embodiment, the electronic device 1 may be implemented so that the pen input device is fitted into the inner space of the first housing 11 or the second housing 12.

FIG. 3 is an exploded perspective view of a part of an electronic device according to an embodiment of the disclosure.

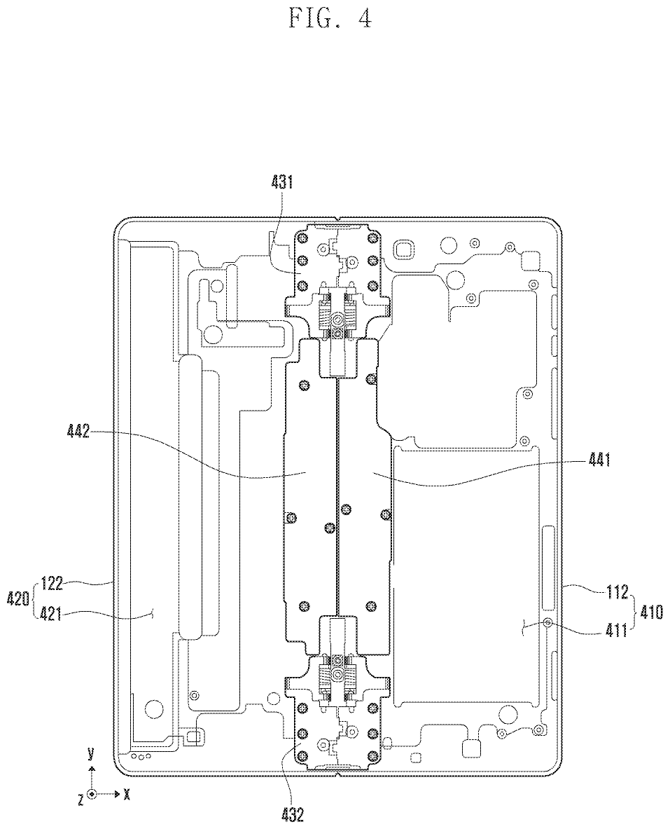

FIG. 4 is a diagram illustrating a part of an electronic device according to an embodiment of the disclosure.

Referring to FIGS. 3 and 4, an electronic device 1 may include a first front case 410, a second front case 420, a hinge assembly 430, a first support plate 441, a second support plate 442, and/or one or more electrical paths 50.

According to an embodiment, the first front case 410 may include the first side member 112 and the first support structure (or first support member) 411. The first support structure 411 may be located in the inner space of the first housing 11 (refer to FIG. 1), and may be connected to the first side member 112, or may be integrally formed with the first side member 112. The second front case 420 may include the second side member 122 and a second support structure (or second support member) 421. The second support structure 421 may be located in the inner space of the second housing 12 (refer to FIG. 1), and may be connected to the second side member 122, or may be integrally formed with the second side member 122. The first support structure 411 and the second support structure 421 is a frame structure located in the electronic device 1 so as to endure the load, and may contribute to the durability or rigidity of the electronic device 1. The first support structure 411 and/or the second support structure 421 may be formed of, for example, a metal material and/or a non-metal material (e.g., polymer). Electronic components or various members related to the electronic components may be disposed in the first front case 410 or the first support structure 411, or may be supported by the first front case 410 or the first support structure 411. Electronic components or various members related to the electronic components may be disposed in the second front case 420 or the second support structure 421, or may be supported by the second front case 420 or the second support structure 421. The first front case 410 or the first support structure 411 may be included in the first housing 11 of the foldable housing 10 (refer to FIG. 1) so as to endure the load, and may contribute to the durability or rigidity of the electronic device 1. The second front case 420 or the second support structure 421 may be included in the second housing 12 of the foldable housing 10 so as to endure the load, and may contribute to the durability or rigidity of the electronic device 1. In a certain embodiment, the first front case 410 or the first support structure 411 may be referred to as other various terms, such as “first frame”, “first frame structure”, or “first framework”. In a certain embodiment, the second front case 420 or the second support structure 421 may be referred to as “second frame”, “second frame structure”, or “second framework”. In a certain embodiment, the first support structure 411 is a first internal structure located in the inner space of the electronic device 1 to correspond to the first housing 11, and in a certain embodiment, it may be referred to as other various terms, such as “first bracket” or “first support member”. In a certain embodiment, the second support structure 421 is a second internal structure located in the inner space of the electronic device 1 to correspond to the second housing 12, and in a certain embodiment, it may be referred to as other various terms, such as “second bracket” or “second support member”. In a certain embodiment, the first support structure 411 may be interpreted as a part of the first housing 11, and the second support structure 421 may be interpreted as a part of the second housing 12.

According to an embodiment, the hinge assembly 430 may include a first hinge 431, a second hinge 432, and/or a hinge housing 30. The first front case 410 and the second front case 420 may be mutually rotatable based on the rotation axis (e.g., folding axis A of FIG. 1) by the first hinge 431 and the second hinge 432. The first hinge 431 and the second hinge 432 may connect the first support structure 411 and the second support structure 421. The first hinge 431 may include, for example, a first part (or first hinge arm) 431a combined with the first support structure 411, a second part (or second hinge arm) 431b combined with the second support structure 421, and a third part 431c connected to the first part 431a and the second part 431b. The first part 431a and the second part 431b may be rotatably connected to the third part 431c. In an embodiment, the first part 431a, the second part 431b, and the third part 432c may be connected to be driven using a gear assembly (or gear structure). The gear assembly may include an assembly in which gears, such as circular gears or conical gears, are engaged with each other, and may allow the first part 431a and/or the second part 431b to be rotated against the third part 432c. For example, the folding axis A of FIG. 1 may be substantially formed by the gear assembly. In an embodiment, the gear assembly may contribute to the rotation of the first part 431a and the second part 431b at the same angle in opposite directions based on the third part 431c when the state of the electronic device 1 is changed (e.g., switching between the unfolding state of FIG. 1 and the folding state of FIG. 2). In a certain embodiment, the hinge implemented to include the gear assembly may be referred to as “gear hinge”. The second hinge 432 may be implemented substantially in the same manner as the first hinge 431, and may include a first part 432a, a second part 432b, and a third part 432c. The first front case 410 combined with the first part 431a of the first hinge 431 and the first part 432a of the second hinge 432 and the second front case 420 combined with the second part 431b of the first hinge 431 and the second part 432b of the second hinge 432 may be mutually rotatable about the third part 431c of the first hinge 431 and the third part 432c of the second hinge 432. The location and the number of hinges are not limited to the illustrated example, and may vary.

According to an embodiment, the first hinge 431 may include an elastic structure for applying elasticity to the rotation of the first part 431a for the third part 431c and the rotation of the second part 431b for the third part 431c. For example, the elastic structure may apply a force to the operation of the gear assembly included in the first hinge 431. For example, the elastic structure may be implemented to include a torsion spring 431d. The second hinge 432 may include an elastic structure implemented substantially in the same manner as the elastic structure included in the first hinge 431. The elastic structure included in the first hinge 431 and the elastic structure included in the second hinge 432 may apply a force for smoothing the state change (e.g., switching between the unfolding state of FIG. 1 and the folding state of FIG. 2) of the electronic device 1 (e.g., semi-automatic state change). For example, if the first housing 11 (refer to FIG. 1) and the second housing 12 (refer to FIG. 1) are changed from a first state (e.g., unfolding state of FIG. 1) in which the first housing 11 and the second housing 12 form an angle of about 180 degrees to a state in which the first housing 11 and the second housing 12 form an angle that is smaller than a reference angle (e.g., about 90 degrees) due to the elastic structure included in the first hinge 431 and the elastic structure included in the second hinge 432, the state is automatically changed to a second state (e.g., folding state of FIG. 2) in which the first housing 11 and the second housing 12 form an angle of about 0 to 10 degrees even with no more external force. For example, if the applied external force is released after the state is changed from the first state to the state in which the angle that is equal to or larger than the reference angle (e.g., about 90 degrees) is formed due to the elastic structure included in the first hinge 431 and the elastic structure included in the second hinge 432, the state may automatically return to the first state. For example, if the state is changed from the second state to the state in which the angle that is larger than the reference angle (e.g., about 90 degrees) due to the elastic structure included in the first hinge 431 and the elastic structure included in the second hinge 432, the state is automatically changed to the first state even with no more external force. For example, if the applied external force is released after the state is changed from the second state to the state in which the angle that is equal to or smaller than the reference angle is formed, the state may automatically return to the second state.

According to an embodiment, the hinge housing 30 may be combined with the third part 431c of the first hinge 431 and the third part 432c of the second hinge 432. The first front case 410 may include the first cover member 451, and the second front case 420 may include the second cover member 452. The first cover member 451 may be connected to the first support structure 411, or may be integrally formed with the first support structure 411. The second cover member 452 may be connected to the second support structure 421, or may be integrally formed with the second support structure. For example, the first cover member 451 and the second cover member 452 may be provided in a curved shape that includes a curved part corresponding to the curved surface included in the hinge housing 30. In a certain embodiment, the first cover member 451 may be referred to as other various terms, such as “first curved member” or “first curved cover”, and the second cover member 452 may be referred to as other various terms, such as “second curved member” or “second curved cover”. In the unfolding state (refer to FIG. 1) of the electronic device 1, the first cover member 451 and the second cover member 452 may cover the hinge housing 30, and the hinge housing 30 may not be substantially exposed to the outside. In the folding state (refer to FIG. 2) of the electronic device 1, the hinge housing 30 may be exposed to the outside between the first cover member 451 and the second cover member 452. In a certain embodiment, the first cover member may be interpreted as a part of the first housing 11, and the second cover member 452 may be interpreted as a part of the second housing 12. In a certain embodiment, the first cover member 451 and the second cover member 452 may be interpreted as a part of the folding part of the foldable housing 10.

According to an embodiment, the first support plate 441 may be combined with the first support structure 411, and the second support plate 442 may be combined with the second support structure 421. For example, using screw fastening (or bolt fastening), the first support plate 441 may be combined with the first support structure 411, and the second support plate 442 may be combined with the second support structure 421. The first support plate 441 and the second support plate 442 may be located at least partly between the first hinge 431 and the second hinge 432. In the unfolding state (refer to FIG. 1) of the electronic device 1, the first support plate 441 and the second support plate 442 may form an angle of about 180 degrees. In the folding state (refer to FIG. 2) of the electronic device 1, the first support plate 441 and the second support plate 442 may be spaced apart from each other and overlap each other, and may form the angle of about 0 to 10 degrees, or may be located substantially in parallel to each other.

According to an embodiment, one or more electrical paths 50 may electrically connect the first electrical element located in the first housing 11 (refer to FIG. 1) and the second electrical element located in the second housing 12 (refer to FIG. 1) with each other. For example, the one or more electrical paths 50 may electrically connect a first printed circuit board located in the first housing 11 (refer to FIG. 1) and a second printed circuit board located in the second housing 12 (refer to FIG. 1) with each other. Signals (e.g., command or data) between the first printed circuit board and the second printed circuit board may be transmitted through the one or more electrical paths. For example, the one or more electrical paths 50 may include a flexible printed circuit board (FPCB) or a rigid flexible printed circuit board (RFPCB) extending to the second housing 12. The one or more electrical paths 50 may be combined with the first support plate 441 and the second support plate 442, and may be supported by the first support plate 441 and the second support plate 442. The one or more electrical paths 50 may include a second part combined with the first support plate 441, a third part combined with the second support plate 442, and a first part between the second part and the third part. The first part may be located to correspond to the hinge assembly 430. The first part may be bent and disposed in accordance with the state change (e.g., switching between the unfolding state of FIG. 1 and the folding state of FIG. 2) of the electronic device 1.

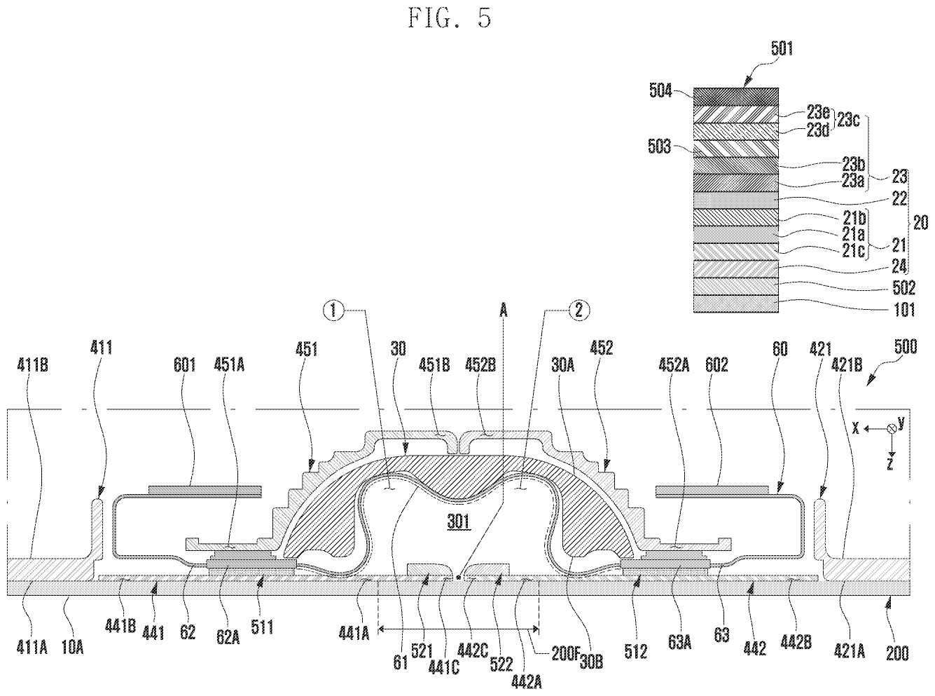

FIG. 5 is a cross-sectional view illustrating a part of an electronic device 1, being cut along line C-C′ of FIG. 1 according to an embodiment of the disclosure.

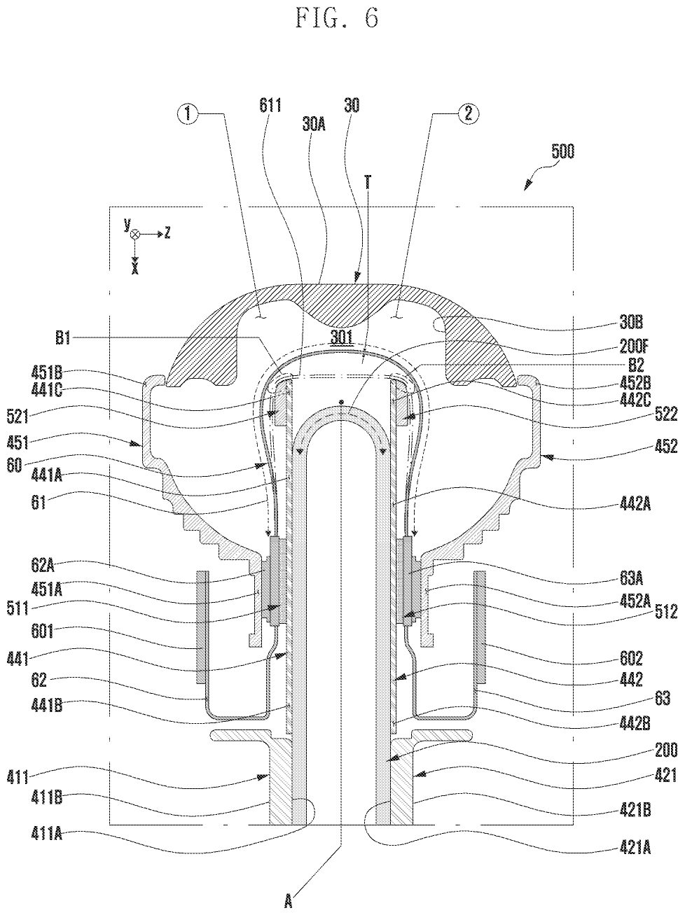

FIG. 6 is a cross-sectional view illustrating a part of an electronic device 1, being cut along line D-D′ of FIG. 2 according to an embodiment of the disclosure.

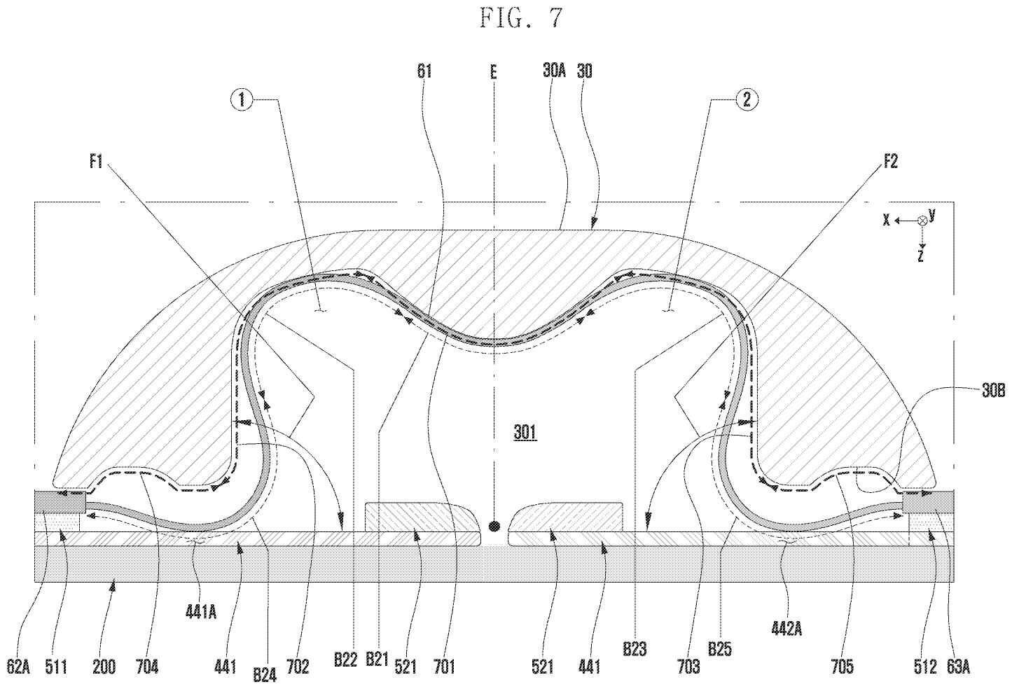

FIG. 7 is an enlarged view illustrating a part of a cross-sectional view of FIG. 5 according to an embodiment of the disclosure.

Referring to FIGS. 5 (depicting a cross-sectional view 500), 6 (depicting a cross-sectional view 600), and 7, an electronic device 1 may include a display assembly 200, a first support structure 411, a second support structure 421, a first cover member 451, a second cover member 452, a hinge housing 30, a flexible printed circuit board 60, a first support plate 441, and/or a second support plate 442.

According to an embodiment, the display assembly 200 (refer to a cross-sectional structure indicated by a reference numeral “501” in FIG. 5) may include a flexible display 20, a front cover 101, an optical transparent adhesive member 502, an electromagnetic induction panel 503, and/or a support sheet 504. The flexible display 20 may be combined with the front cover 101 using the optical transparent adhesive member 502 (e.g., optical clear adhesive (OCA), optical clear resin (OCR), or super view resin (SVR)). The front cover 101 (e.g., window) may protect the flexible display 20 from the outside by covering the flexible display 20. The front cover 101 may be implemented in the form of a thin film (e.g., thin film layer) having flexibility. For example, the front cover 101 may include a plastic film (e.g., polyimide film) or a thin film glass (e.g., ultra-thin glass). In a certain embodiment, the front cover 101 may include a plurality of layers. For example, the front cover 101 may be in the form in which various coated layers are disposed on the plastic film or the thin film glass. For example, the front cover 101 may be in the form in which at least one protection layer or coated layer including a polymer material (e.g., polyester terephthalate (PET), polyimide (PI), or thermoplastic polyurethane (TPU)) is disposed on the plastic film or the thin film glass. In a certain embodiment, the front cover 101 may be defined or interpreted as a constituent element included in the flexible display 20. For example, the flexible display 20 may include a display panel 21, a base film 22, a lower panel 23, and/or an optical layer 24. The display panel 21 may be located between the optical layer 24 and the base film 22. The base film 22 may be located between the display panel 21 and the lower panel 23. The optical layer 24 may be located between the optical transparent adhesive member 502 and the display panel 21. Various polymer adhesive members (not illustrated) may be disposed between the display panel 21 and the base film 22, between the base film 22 and the lower panel 23, and/or between the display panel 21 and the optical layer 24. The display panel 21 may include, for example, a light-emitting layer 21a, a thin film transistor (TFT) film 21b, and/or an encapsulation (e.g., thin-film encapsulation (TFE)) layer 21c. The light-emitting layer 21a may include, for example, a plurality of pixels implemented as a light-emitting element, such as organic light emitting diode (OLED) or micro light emitting diode (LED). The light-emitting layer 21a may be disposed on the TFT film 21b through organic evaporation. The TFT film 21b may be located between the light-emitting layer 21a and the base film 22. The TFT film 21b may indicate a film structure in which at least one TFT is disposed on a flexible board (e.g., PI film) through a series of processes, such as deposition, patterning, and etching. The at least one TFT may turn on/off the pixel and adjust the brightness of the pixel by controlling current for the light-emitting element of the light-emitting layer 21a. For example, the at least one TFT may be implemented by amorphous silicon (a-Si) TFT, liquid crystalline polymer (LCP) TFT, low-temperature polycrystalline oxide (LTPO) TFT, or low-temperature polycrystalline silicon (LTPS). The display panel 21 may include a storage capacitor, and the storage capacitor may maintain a voltage signal for the pixel, maintain the voltage input to the pixel for one frame, or reduce a gate voltage change of the TFT due to current leakage for a light-emitting time. By a routine (e.g., initialization and data write) for controlling at least one TFT, the storage capacitor may maintain the voltage being applied to the pixel at predetermined intervals. In an embodiment, the display panel 21 may be implemented based on an OLED, and the encapsulation layer 21c may cover the light-emitting layer 21a. Since an organic material that emits light and an electrode in an OLED react very sensitively on oxygen and/or moisture, and thus light-emitting characteristics thereof may be lost, the encapsulation layer 21c may seal the light-emitting layer 21a so that the oxygen and/or moisture does not penetrate into the OLED. The encapsulation layer 31c may serve as a pixel protection layer for protecting a plurality of pixels of the light-emitting layer 31a. The base film 22 may include a flexible film formed of polymer, such as polyimide or polyester (PET) or plastic. The base film 32 may serve to support and protect the display panel 21. In a certain embodiment, the base film 22 may be referred to as a protective film, a back film, or a back plate. The lower panel 23 may include a plurality of layers for various functions. Between the plurality of layers included in the lower panel 23, various polymer adhesive members (not illustrated) may be disposed. For example, the lower panel 23 may include a shading layer 23a, a buffer layer 23b, or a lower layer 23c. The shading layer 23a may be located between the base film 22 and the buffer layer 23b. The buffer layer 23b may be located between the shading layer 23a and the lower layer 23c. The buffer layer 23b may block at least a part of the light incident from the outside. For example, the shading layer 23a may include an embo layer. The embo layer may be a black layer including a rugged pattern. The buffer layer 23b may buffer an external impact being applied to the flexible display 20. For example, the buffer layer 23b may include a sponge layer or a cushion layer. The lower layer 23c may diffuse, dissipate, or insulate the heat generated from the electronic device 1 or the flexible display 20. The lower layer 23c may absorb or shield electromagnetic waves. The lower layer 23c may mitigate an external impact being applied to the electronic device 1 or the flexible display 20. For example, the lower layer 23c may include a composite sheet 23d or a conductive sheet 23e. In an embodiment, the composite sheet 23d may be a sheet obtained by combining and processing layers or sheets having different properties. For example, the composite sheet 23d may include at least one of polyimide or graphite. The composite sheet 23d may be replaced by a single sheet including one material (e.g., polyimide or graphite). The composite sheet 23d may be located between the buffer layer 23b and the conductive sheet 23e. The conductive sheet 23e may reduce or shield electromagnetic interference (EMI) against the flexible display 20. The conductive sheet 23e may include copper, but the conductive sheet is not limited thereto, and other various metal materials may be included therein. In a certain embodiment, at least a part of the lower layer 23c may be a conductive member (e.g., metal plate), and may be used to shield ambient noises and to dissipate the heat emitted from a neighboring heat emitting component (e.g., display driving circuit (e.g., DDI)). The conductive member may include, for example, at least one of copper (Cu), aluminum (Al), stainless steel (SUS), or CLAD (laminated member on which SUS and Al are alternately disposed). The lower layer 23c may include various layers for other various functions. In a certain embodiment (not illustrated), on the rear surface of the display panel 21, at least one additional polymer layer (e.g., layer including PI, PET, or TPU) may be further disposed in addition to the base film 22. In various embodiments, at least one of a plurality of layers (e.g., shading layer 23a, buffer layer 23b, composite sheet 23d, and conductive sheet 23e) included in the lower panel 23 may be omitted. In a certain embodiment, the disposition order of the plurality of layers included in the lower panel 23 may not be limited to the illustrated examples, but may be variously changed. For example, the optical layer 24 may include a polarizing layer (or polarizer) or a retardation layer (or retarder). The polarizing layer and the retardation layer may improve outdoor visibility of the screen. For example, the optical layer 24 may selectively pass the light that is generated from the light source of the display panel 21 and vibrates in a predetermined direction. In a certain embodiment, one layer obtained by merging the polarizing layer and the retardation layer may be provided, and such a layer may be defined as a “circular polarization layer”. The optical transparent adhesive member 26 may be located between the front cover 101 and the optical layer 24. In a certain embodiment, the polarizing layer (or circular polarization layer) may be omitted, and in this case, a block pixel define layer (PDL) and/or a color filter may be included in replacement of the polarizing layer. In an embodiment, the display assembly 200 may include a touch sensing circuit (e.g., touch sensor) (not illustrated). The touch sensing circuit may be implemented by a transparent conductive layer (or film) based on various conductive materials, such as indium tin oxide (ITO). For example, the touch sensing circuit may be disposed between the front cover 101 and the optical layer 24 (e.g., add-on type). As another example, the touch sensing circuit may be disposed between the optical layer 24 and the display panel 21 (e.g., on-cell type). As another example, the display panel 21 may include a touch sensing circuit or a touch sensing function (e.g., in-cell type). In an embodiment (not illustrated), the flexible display 20 may include a conductive pattern, such as a metal mesh (e.g., aluminum metal mesh), as a touch sensing circuit disposed on the encapsulation layer 21c between the encapsulation layer 21c and the optical layer 24. For example, to correspond to the flexing of the flexible display 20, the metal mesh may have higher durability than that of the transparent conductive layer implemented by ITO. In a certain embodiment, the flexible display 20 may further include a pressure sensor (not illustrated) that can measure the strength (pressure) of a touch. The plurality of layers included in the display panel 21 or the lower panel 23 may have various lamination structures or lamination orders. Depending on the trend of the providing type or convergence, the flexible display 20 may be implemented through omission of some of constituent elements or through addition of other constituent elements. In an embodiment, the electromagnetic induction panel (e.g., digitizer) 503 may be located between the buffer layer 23b and the lower layer 23c. In a certain embodiment, the electromagnetic induction panel 503 may be located between the composite sheet 23d and the conductive sheet 23e of the lower layer 23c. In a certain embodiment, the electromagnetic induction panel 503 may be located between the shading layer 23a and the buffer layer 23b. The electromagnetic induction panel 503 may be implemented in the form of a flexible film or a flexible sheet. For example, the electromagnetic induction panel 503 may be provided as a flexible printed circuit board. If an alternating current (AC) is supplied to the electromagnetic induction panel 503, an electromagnetic field may be formed by a plurality of electrode patterns included in the electromagnetic induction panel 503. The pen input device may be implemented by an electromagnetic induction method (e.g., electromagnetic resonance (EMR) method. The pen input device may include a resonance circuit, and the resonance circuit may interwork with the electromagnetic induction panel 503. If a pen tip of the pen input device becomes close to the front surface 10A of the electronic device 1, current may flow in a coil included in the resonance circuit of the pen input device by electromagnetic induction. The pen input device may generate a signal about a user input on the screen (e.g., radio frequency signal) (e.g., location signal, pen pressure signal, and/or angle signal) using energy that is supplied from the electromagnetic induction panel 503, and may transmit the generated signal to the screen (e.g., electromagnetic induction panel 503). The electromagnetic induction panel 503 may include a shield sheet. The shield sheet may be located on the rear surface (e.g., in the illustrated embodiment, surface of the flexible printed circuit board that faces the conductive sheet 23e) of the flexible printed circuit board including the plurality of electrode patterns. The shield sheet may prevent interference between components included in the electronic device 1 due to the electromagnetic field generated from the components. The shield sheet may allow an input from the pen input device to be accurately transferred to the coil included in the electromagnetic induction panel 503 by blocking the electromagnetic field generated from the components. In a certain embodiment, the electromagnetic induction panel 503 may be defined or interpreted as a constituent element included in the flexible display 20. According to various embodiments, the pen input device may be implemented in an active electrical stylus (AES) method or an electric coupled resonance (ECR) method. In this case, the electromagnetic induction panel 503 may be omitted.

According to an embodiment, the display assembly including the sub-display 210 (refer to FIG. 1 or 2) may be located to correspond to the fourth cover area \textcircled{d}, and may be implemented to include at least a part of the display assembly 200. In a certain embodiment, the display assembly including the sub-display 210 may be implemented by omitting some of the constituent elements included in the cross-sectional structure 501 or by adding one or more other constituent elements.

According to an embodiment, the support sheet 504 may be disposed on the rear surface of the flexible display 20. For example, the support sheet 504 may be disposed on the rear surface of the lower panel 23 included in the flexible display 20. The support sheet 5r04 may contribute to the durability of the display assembly 200 or the flexible display 20. For example, the support sheet 504 may reduce an influence that the load or stress, which may be generated during the switching between the unfolding state of FIG. 1 and the folding state of FIG. 2, exerts on the flexible display 20. The support sheet 504 may be formed of various metal materials and/or non-metal materials (e.g., polymer). The support sheet 504 may include, for example, stainless steel. As another example, the support sheet 504 may include engineering plastic. In a certain embodiment, the support sheet 504 may be implemented integrally with the flexible display 20. In a certain embodiment, the support sheet 504 may be omitted.

According to an embodiment, the support sheet 504 may include a lattice structure provided to a part corresponding to the folding cover area F (refer to FIG. 1). The lattice structure may include, for example, a plurality of openings (or slits). For example, the plurality of openings may be periodically formed, may have substantially the same form, and may be repeatedly arranged at predetermined intervals. In a certain embodiment, the lattice structure including a plurality of openings may be referred to as “opening pattern”. The lattice structure may contribute to the flexibility of a part of the display assembly 200 corresponding to the folding cover area F. In a certain embodiment, the support sheet 504 may include a recess pattern (not illustrated) including a plurality of recesses in replacement of the lattice structure. In various embodiments, the lattice structure or the recess pattern that contributes to the flexibility of the display assembly 200 may be further expanded to another part. In a certain embodiment, the support sheet 504 including the lattice structure or the recess pattern or the corresponding conductive member may be provided as a plurality of layers. In a certain embodiment, the support sheet 504 may be omitted, or may be defined or interpreted as a constituent element included in the flexible display 20.

According to an embodiment, the first support structure 411 may include a first front area 411A directed to the front surface 10A of the electronic device 1 (refer to FIG. 1) and a first rear area 411B directed to the rear surface 10B (refer to FIG. 1) of the electronic device 1. The second support structure 421 may include a second front area 421A directed to the front surface 10A of the electronic device 1 and a second rear area 421B directed toward the rear surface 10B of the electronic device 1. A part (e.g., first display area) of the display assembly 200 may be disposed on the first front area 411A of the first support structure 411, and may be supported by the first support structure 411. Another part (e.g., second display area) of the display assembly 200 may be disposed on the second front area 421A of the second support structure 421, and may be supported by the second support structure 421. For example, the display assembly 200 may be combined with the first support structure 411 and the second support structure 421 using various adhesive materials, such as a thermal reaction adhesive material, a photoreaction adhesive material, a general adhesive, and/or a double-sided tape.

According to an embodiment, the first support plate 441 combined with the first support structure 411 and the second support plate 442 combined with the second support structure 421 may support a partial area of the display assembly 200 corresponding to the folding cover area F in the unfolding state (refer to FIG. 1) of the electronic device 1.

According to an embodiment, the electronic device 1 (refer to FIG. 1) may include a first printed circuit board (e.g., first printed circuit board (PCB) or first printed board assembly (PBA)) disposed on the first rear area 411B of the first support structure 411 between the first support structure 411 and the first rear cover 111 (refer to FIG. 1). The electronic device 1 may include a first battery disposed on the first rear area 411B of the first support structure 411 between the first support structure 411 and the first rear cover 111.

According to an embodiment, the electronic device 1 (refer to FIG. 1) may include a second printed circuit board (e.g., first PCB or second PBA) disposed on the second rear area 421B of the second support structure 421 between the second support structure 421 and the second rear cover 121 (refer to FIG. 1). The electronic device 1 may include a second battery disposed on the second rear area 421B of the second support structure 421 between the second support structure 421 and the second rear cover 121.

According to various embodiments, the first printed circuit board disposed in the first support structure 411 or the second printed circuit board disposed in the second support structure 421 may include a primary PCB, a secondary PCB, and an interposer board between the primary PCB and the secondary PCB. The interposer board may include, for example, a plurality of conductive vias for electrically connecting the primary PCB and the secondary PCB with each other. At least some of the plurality of conductive vias included in the interposer board may be some signal lines for transferring signals between a first electronic component disposed on the primary PCB and a second electronic component disposed on the secondary PCB. In a certain embodiment, some of the plurality of conductive vias included in the interposer board may be some of ground paths that electrically connect a first ground plane included in the primary PCB and a second ground plane included in the secondary PCB.

According to an embodiment, the flexible printed circuit board 60 (e.g., one of electrical paths 50 of FIG. 3) may electrically connect the first printed circuit board disposed in the first support structure 411 and the second printed circuit board disposed in the second support structure 421 with each other. One end part 601 of the flexible printed circuit board 60 may include a first connector for electrically connecting to the first printed circuit board, and the other end part 602 of the flexible printed circuit board 60 may include a second connector for electrically connecting to the second printed circuit board.

According to an embodiment, the flexible printed circuit board 60 may include a first part 61 corresponding to the folding part of the foldable housing 10 (refer to FIG. 1), a second part 62 extending from the first part 61 to the first housing 11 (refer to FIG. 1), and a third part 63 extending from the first part 61 to the second housing 12 (refer to FIG. 1). The first part 61 may be flexible, and may be deformed depending on the state change (e.g., switching between the unfolding state of FIG. 1 and the folding state of FIG. 2) of the electronic device 1. The second part 62 may be combined with the first support plate 441 using a first adhesive member 511 of various polymers. The third part 63 may be combined with the second support plate 442 using a second adhesive member 512 of various polymers.

According to an embodiment, the flexible printed circuit board 60 may include a flexible part and a rigid part, or may include a plurality of parts having different flexibilities. The flexible printed circuit board 60 disclosed in the disclosure may be defined or interpreted as a printed circuit board including at least partly flexible part. For example, the rigid flexible printed circuit board (RFPCB) may include a rigid part, but may be interpreted as one of various types of flexible printed circuit boards.

According to an embodiment, a part 62A (hereinafter, referred to as “first fixing part”), being combined with the first support plate 441, of the second part 62 of the flexible printed circuit board 60 may be substantially rigid, and another part of the second part 62 may be flexible. A part 63A (hereinafter, referred to as “second fixing part”), being combined with the second support plate 442, of the third part 63 of the flexible printed circuit board 60 may be substantially rigid, and another part of the third part 63 may be flexible. For example, the first fixing part 62A and/or the second fixing part 63B may be provided in the form of a substantially rigid printed circuit board. As another example, a reinforcement member or a reinforcement structure, such as a stiffener, may be included in or added to the first fixing part 62A and the second fixing part 63A. In a certain embodiment, using a mechanical connection, such as screw fastening, instead of the adhesive member, the first fixing part 62A may be combined with the first support plate 441, and the second fixing part 63A may be combined with the second support plate 442.

According to various embodiments, the first fixing part 62A and/or the second fixing part 63A may be substantially flexible.

According to an embodiment, the hinge housing 30 may include a first surface 30A corresponding to the first cover member 451 and the second cover member. In the unfolding state of the electronic device 1, the first surface 30A may be hidden by the first cover member 451 and the second cover member 452, and may not be exposed to the outside. When the electronic device 1 is switched from the unfolding state to the folding state (refer to FIG. 2), the gap B (refer to FIG. 1) between the first cover member 451 and the second cover member 452 is opened, and the first surface 30A is exposed to the outside to provide a part of an external appearance of the electronic device 1. In an embodiment, the first fixing part 62A of the second part 62 included in the flexible printed circuit board 60 may be located between the first support plate 441 and the first cover member 451. In an embodiment, the second fixing part 63A of the third part 63 included in the flexible printed circuit board 60 may be located between the second support plate 442 and the second cover member 452. The first surface 30A of the hinge housing 30 may include one area including a curved surface corresponding to the first cover member 451 and the other area including a curved surface corresponding to the second cover member 452. As seen from a cross section of an x-z plane illustrated in FIG. 5 (e.g., cross section of the x-z plane that is vertical to the direction of the folding axis A), the first cover member 451 may have a curved shape extending from the first end part 451A to the second end part 451B so as to cover the one area of the first surface 30A. As seen from the cross section of the x-z plane illustrated in FIG. 5, the second cover member 452 may have a curved shape extending from the third end part 452A to the fourth end part 452B so as to cover the other area of the first surface 30A. In an embodiment, the first fixing part 62A of the second part 62 included in the flexible printed circuit board 60 may be located between the first end part 451A of the first cover member 451 and the first support plate 441. In an embodiment, the second fixing part 63A of the third part 63 included in the flexible printed circuit board 60 may be located between the third end part 452A of the second cover member 452 and the second support plate 442. The second part 62 of the flexible printed circuit board 60 may indicate a part extending from the first part 61 corresponding to the folding part of the foldable housing 10 (refer to FIG. 1) and passing between the first end part 451A of the first cover member 451 and the first support plate 441. The third part 63 of the flexible printed circuit board 60 may indicate a part extending from the first part 61 corresponding to the folding part of the foldable housing 10 and passing between the third end part 452A of the second cover member 452 and the second support plate 442. If the electronic device 1 is switched from the unfolding state (refer to FIG. 5) to the folding state (refer to FIG. 6), an area in which the first cover member 451 overlaps the first surface 30A of the hinge housing 30 and an area in which the second cover member 452 overlaps the first surface 30A of the hinge housing 30 may be reduced. In the unfolding state of the electronic device 1, the second end part 451B of the first cover member 451 and the fourth end part 452B of the second cover member 452 come in contact with each other, and the gap B (refer to FIG. 1) may not exist substantially, and the hinge housing 30 may not be exposed to the outside. When the electronic device 1 is switched from the unfolding state to the folding state, the gap B between the second end part 451B of the first cover member 451 and the fourth end part 452B of the second cover member 452 is opened, and the first surface 30A of the hinge housing 30 is exposed to the outside to provide a part of an external appearance of the electronic device 1.

According to various embodiments, using a mechanical connection, such as screw fastening, or bonding including an adhesive material, the first fixing part 62A of the second part 62 included in the flexible printed circuit board 60 may be combined with the first end part 451A of the first cover member 451, and the second fixing part 63A of the third part 63 included in the flexible printed circuit board 60 may be combined with the third end part 452A of the second cover member 452.

According to an embodiment, the hinge housing 30 may be combined with the third part 431c, corresponding to the folding axis A, of the first hinge 431 (refer to FIG. 4) and the third part 432c, corresponding to the folding axis A, of the second hinge 432 (refer to FIG. 4). During the state change (e.g., switching between the unfolding state of FIG. 1 and the folding state of FIG. 2) of the electronic device 1, the first housing 11 (refer to FIG. 1) and the second housing 12 (refer to FIG. 1) may be rotated at the same angle in opposite directions based on the hinge housing 30 combined with the third part 431c of the first hinge 431 and the third part 432c of the second hinge 432. During the state change of the electronic device 1, the first support structure 411 located in the first housing 11 and the second support structure 421 located in the second housing 12 may be rotated at the same angle in the opposite directions based on the hinge housing 30 combined with the third part 431c of the first hinge 431 and the third part 432c of the second hinge 432. During the state change of the electronic device 1, the first support plate 441 connected to the first support structure 411 and the second support plate 442 connected to the second support structure 421 may be rotated at the same angle in the opposite directions based on the hinge housing 30 combined with the third part 431c of the first hinge 431 and the third part 432c of the second hinge 432.

According to an embodiment, in the unfolding state (refer to FIG. 5) of the electronic device 1, the first support plate 441 and the second support plate 442 may form an angle of about 180 degrees. In the folding state (refer to FIG. 6) of the electronic device 1, the first support plate 441 and the second support plate 442 may be spaced apart from each other to face each other, and may form an angle of about 0 to 10 degrees, or may be located substantially in parallel to each other. As seen from a cross section of an x-z plane illustrated in FIG. 5 or 6 (e.g., cross section of the x-z plane that is vertical to the direction of the folding axis A), the first support plate 441 may include the first plate area 441A and the third plate area 441B. In an embodiment, the first fixing part 62A of the flexible printed circuit board 60 may be combined with a part adjacent to the first plate area 441A of the third plate area 441B using the first adhesive member 511. The third plate area 441B may be combined with the first support structure 411. As seen from the cross section of the x-z plane illustrated in FIG. 5 or 6, the second support plate 442 may include the second plate area 442A and the fourth plate area 442B. In an embodiment, the second fixing part 63A of the flexible printed circuit board 60 may be combined with a part adjacent to the second plate area 442A of the fourth plate area 442B using the second adhesive member 512. The fourth plate area 442B may be combined with the second support structure 421.

According to an embodiment, in the unfolding state (refer to FIG. 5) of the electronic device 1, as seen from the cross section of the x-z plane (e.g., cross section of the x-z plane that is vertical to the direction of the folding axis A), the first plate area 441A of the first support plate 441 and the second plate area 442A of the second support plate 442 may form an angle of about 180 degrees, and may be located to face the second surface 30B of the hinge housing 30. In the folding state (refer to FIG. 6) of the electronic device 1, as seen from the cross section of the x-z plane, the first plate area 441A and the second plate area 442A form an angle of about 0 to 10 degrees, and the first plate area 441A may be located to face the first cover member 451, and the second plate area 442A may be located to face the second cover member 452.

According to an embodiment, as seen from the cross section of the x-z plane (e.g., cross section of the x-z plane that is vertical to the direction of the folding axis A), corresponding to the folding display area 200F that overlaps the folding cover area F (refer to FIG. 1) of the display assembly 200, the first plate area 441A of the first support plate 441 may include the first end area 441C, and the second plate area 442A of the second support plate 442 may include the second end area 442C. In the unfolding state (refer to FIG. 5) of the electronic device 1, the first end area 441C of the first plate area 441A and the second end area 442C of the second plate area 442A may support the folding display area 200F disposed in the form of a plane. In the unfolding state of the electronic device 1, the first end area 441C and the second end area 442C may contribute to the maintaining of the folding display area 200F in the form of a plane. In the folding state (refer to FIG. 6) of the electronic device 1, the folding display area 200F in a curved shape may be located between the first end area 441C of the first plate area 441A and the second end area 442C of the second plate area 442A due to the location of the folding axis A. In an embodiment, the remaining area of the first support plate 441 except the first end area 441C and/or the remaining area of the second support plate 442 except the second end area 442C may be combined with the display assembly 200 using the adhesive member. In a certain embodiment, the remaining area of the first support plate 441 except the first end area 441C and/or the remaining area of the second support plate 442 except the second end area 442C may be in a separated state from the display assembly 200.

According to an embodiment, the hinge housing 30 may include the second surface 30B that is located on an opposite side of the first surface 30A and is not exposed to the outside to correspond to the first part 61 of the flexible printed circuit board 60. In an embodiment, the hinge housing 30 may include a recess 301 provided on the second surface 30B. The first plate area 441A of the first support plate 441 and the second plate area 442A of the second support plate 442 may form an angle of about 180 degrees, and may be located to face the second surface 30B of the hinge housing 30 in the unfolding state (refer to FIG. 5) of the electronic device 1. When the electronic device 1 is in the unfolding state rather than the folding state, the second surface 30B of the hinge housing 30 or the recess 301 may be substantially covered by the first plate area 441A and the second plate area 442A. In an embodiment, in the unfolding state of the electronic device 1, the first part 61 of the flexible printed circuit board 60 may be located in a space surrounded by the second surface 30B of the hinge housing 30, the first plate area 441A of the first support plate 441, and the second plate area 442A of the second support plate 442. In an embodiment, in the unfolding state of the electronic device 1, the first part 61 of the flexible printed circuit board 60 may be located in the form that corresponds to the space surrounded by the second surface 30B of the hinge housing 30, the first plate area 441A of the first support plate 441, and the second plate area 442A of the second support plate 442. When the electronic device 1 is switched from the folding state to the unfolding state, the recess 301 of the hinge housing 30 may guide the deformation of the first part 61 of the flexible printed circuit board 60.

According to an embodiment, in the folding state of the electronic device 1, the first plate area 441A of the first support plate 441 and the second plate area 442A of the second support plate 442 may form an angle of about 0 to 10 degrees, and the first end area 441C of the first support plate 441 and the second end area 442C of the second support plate 442 may be located outside the recess 301 of the hinge housing 30. In a certain embodiment, in the folding state of the electronic device 1, the first end area 441C and the second end area 442C may be partly inserted into the recess 301 of the hinge housing 30. When the electronic device 1 is switched from the unfolding state to the folding state, the first part 61 of the flexible printed circuit board 60 may be deformed into another form that is different from the unfolding state of the electronic device 1 based on the self-elasticity to correspond to the change of the spatial location relationship among the hinge housing 30, the first support plate 441, and the second support plate 442.

According to an embodiment, the first part 61 of the flexible printed circuit board 60 may have a length of a designated range that can reduce the stress occurrence in the unfolding state and the folding state of the electronic device 1. The length of the designated range may indicate, for example, a length that can reduce the damage or permanent deformation of the first part 61 included in the flexible printed circuit board 60 in the unfolding state and the folding state of the electronic device 1. As seen from the cross section of the x-z plane (e.g., cross section of the x-z plane that is vertical to the direction of the folding axis A), the first part 61 of the flexible printed circuit board 60 may have a thickness T between one surface and the other surface located on opposite sides to each other. The bending stress occurring in the bending area of the first part 61 may occur as the force increasing on one surface of the bending area (e.g., tensile stress) and the force decreasing on the other surface of the bending area (e.g., compressive stress) collide with each other. For example, the bending stress occurring in the bending area of the first part 61 may be in proportion to the modulus of longitudinal elasticity (degree of resistance for tensile or compression) of the first part 61 and/or the thickness T of the first part 61. The bending stress occurring in the bending area of the first part 61 may be in inverse proportion to a curvature radius. As indicated by the reference numeral “611” of FIG. 7, there may be a first comparison example in which the first part 61 is formed with a length that is shorter than the length of the designated range. In case of the first comparison example, if the electronic device 1 is switched from the unfolding state to the folding state, due to the change of the relative locations between the first support plate 441 and the second support plate 442 which are combined with the flexible printed circuit board 60, the first part 61 may include a first bending area B1 supported and bent by the first end area 441C of the first support plate 441 and a second bending area B2 supported and bent by the second end area 442C of the second support plate 442. In the first comparison example, the first bending area B1 and the second bending area B2 may be formed with a curvature radius that is smaller than the threshold curvature radius, and thus a bending stress that exerts an influence on the damage of the first part 61 may occur. For example, in case of the first comparison example, a yield stress or a bending stress that is greater than the yield stress may occur, and due to this, the first part 61 may be damaged or permanently deformed. In case of the first comparison example, if the switching of the electronic device 1 between the folding state and the unfolding state is repeated, the bending stress occurring in the first bending area B1 and/or the second bending area B2 may cause the damage or the permanent deformation through the deterioration or loss of the elastic force due to fatigue accumulation. In an embodiment of the disclosure in which the first part 61 is formed with the length of the designated range, if the electronic device 1 is switched from the unfolding state to the folding state, the first part 61 is bent with no support of the first end area 441C of the first support plate 441 and the second end area 442C of the second support plate 442, and thus may not include the bending area that is bent with the curvature radius that is smaller than the threshold curvature radius. In a certain embodiment, if the first part 61 is implemented to have the length of the designated range, or to be supported and bent by the first end area 441C and the second end area 442C in the folding state of the electronic device 1, the first end area 441C and the second end area 442C may be formed to include a slow curved surface to reduce the bending stress.

According to various embodiments, a first buffer member 521 may be disposed on the first end area 441C of the first support plate 441, and a second buffer member 522 may be disposed on the second end area 442C of the second support plate 442. In the folding state of the electronic device 1, the first part 61 of the flexible printed circuit board 60 may be supported by the first buffer member 521 and the second buffer member 522. In the folding state of the electronic device 1, the first buffer member 521 and the second buffer member 522 may contribute to the stable location of the first part 61 based on the elasticity thereof without substantially generating the stress influence exerted on the damage of the first part 61. For example, the first buffer member 521 or the second buffer member 522 may include a flexible member, such as sponge.

According to an embodiment, as seen from the cross section of the plane that is vertical to the direction of the folding axis A, the second surface 30B of the hinge housing 30 may include a first area 701, a second area 702, a third area 703, a fourth area 704, and/or a fifth area 705. The recess 301 may be provided by the first area 701, the second area 702, and the third area 703. The first area 701 may be aligned with the folding axis A, and may protrude (e.g., convex part) in the first direction directed to the folding axis A. For example, the first area 701 may include a convex surface that is curved in the first direction directed to the folding axis A. As seen from the x-z cross section, the first area 701 may include a convex surface in the form in which it becomes narrowed in the first direction. Both sides of the first area 701 may be symmetrical about the axis (hereinafter, referred to as “center axis”) that passes the folding axis A and is vertical to the folding axis A. The second area 702 may extend from one end part of the first area 701. The third area 703 may extend from the other end part of the first area 701. The second area 702 and the third area 703 may be located on opposite sides, being interposed by the first area 701. In an embodiment, the second area 702 and the third area 703 may be located symmetrically about the first area 701 or the center axis E.

According to an embodiment, the recess 301 may include a first concave part \textcircled{1} which is provided to a part of the first area 701 and the second area 702, and is carved in a second direction that is opposite to the first direction. The recess 301 may include a first concave part \textcircled{1} which is formed on a part of the first area 701 and the second area 702, and is carved in the second direction that is opposite to the first direction, and a second concave part \textcircled{2} which is formed on the part of the first area 701 and the third area 703, and is carved in the second direction. In an embodiment, as seen from the cross section of the plane that is vertical to the direction of the folding axis A, both sides of the recess 301 may be symmetrical about the center axis E. The fourth area 704 may extend from the second area 702, and the second area 702 may connect the first area 701 and the fourth area 704 with each other. The fifth area 705 may extend from the third area 703, and the third area 703 may connect the first area 701 and the fifth area 705 with each other. The recess 301 may indicate a carved shape between the fourth area 704 and the fifth area 705 on the second surface 30B. In an embodiment, the fourth area 704 and the fifth area 705 may be located symmetrically about the recess 301 or the center axis E.

According to an embodiment, the first area 701 and the second area 702, and/or the first area 701 and the third area 703 may be smoothly connected with each other. In a certain embodiment, edges may be formed on a boundary between the first area 701 and the second area 702 and/or a boundary between the first area 701 and the third area 703.

According to an embodiment, the first area 701 may be formed with a height that does not protrude against the fourth area 704 and the fifth area 705 in the first direction directed to the folding axis A.

According to an embodiment, in the folding state of the electronic device 1, the first part 61 of the flexible printed circuit board 60 may be located to be spaced apart from the second surface 30B (or an area forming the recess 301 on the second surface 30B) of the hinge housing 30.

According to an embodiment, if the electronic device 1 is switched from the folding state to the unfolding state, the first part 61 of the flexible printed circuit board 60 may be deformed in the form in which it does not include the bending area bent with the curvature radius that is smaller than the threshold curvature radius, and may be located in the recess 301 of the hinge housing 30. The first area 701, the second area 702, and the third area 703 that form the recess 301 may contribute to the deformation of the first part 61 of the flexible printed circuit board 60 so that the first part 61 includes the bending area bent with the threshold curvature radius or the curvature radius that is larger than the threshold curvature radius. For example, in the unfolding state of the electronic device 1, the first part 61 may include a first bending area B21, a second bending area B22, a third bending area B23, a fourth bending area B24, and a fifth bending area B25 based on the point of inflection. The first bending area B21, the second bending area B22, the third bending area B23, the fourth bending area B24, and the fifth bending area B25 may be formed to correspond to the space surrounded by the first plate area 441A of the first support plate 441, the second plate area 442A of the second support plate 442, and the second surface 30B of the hinge housing 30. In an embodiment, the area forming the recess 301 on the second surface 30B may guide the deformation thereof so that the first part 61 having the length of the designated range is located in the space surrounded by the first plate area 441A, the second plate area 442A, and the second surface 30B while reducing the bending stress. In an embodiment, the first bending area B21, the second bending area B22, the third bending area B23 may be formed to be supported by the area forming the recess 301 on the second surface 30B. In the first part 61, the second bending area B22 between the first bending area B21 and the fourth bending area B24 may be bent to correspond to the first concave part \textcircled{1}. In the first part 61, the third bending area B23 between the first bending area B21 and the fifth bending area B25 may be bent to correspond to the second concave part \textcircled{2}. In the first part 61, the first bending area B21 between the second bending area B22 and the third bending area B23 may be bent to correspond to the first area 701 on the contrary to the second bending area B22 and the third bending area B23. In the flexible printed circuit board 60, the fifth bending area B25 between the second fixing part 63A and the third bending area B23 may be bent on the contrary to the third bending area B23. In an embodiment, as seen from the cross section of the plane that is vertical to the direction of the folding axis A, both sides of the recess 301 may be symmetrical about the center axis E, and in the unfolding state of the electronic device 1, the recess 301 may contribute to the symmetrical location of the first part 61 of the flexible printed circuit board 60. In the unfolding state of the electronic device 1, the first part 61 of the flexible printed circuit board 60 is symmetrically located, and may contribute to the reduction of the damage or the permanent deformation of the first part 61 through reduction of the phenomenon that the bending area on any one side where the bending stress is concentrated based on the center axis E is formed. In an embodiment, in the unfolding state of the electronic device 1, the first plate area 441A of the first support plate 441 and the second plate area 442A of the second support plate 442 may support the first part 61 so that the first part 61 of the flexible printed circuit board 60 is located in the recess 301 of the hinge housing 30. For example, the first bending area B21, the second bending area B22, and the third bending area B23 may be supported by the area that forms the recess 301 on the second surface 30B of the hinge housing 30, the fourth bending area B24 may be supported by the first plate area 441A, the fifth bending area B25 may be supported by the second plate area 442A, and the first part 61 of the flexible printed circuit board 60 may be stably located in the space surrounded by the second surface 30B, the first plate area 441A, and the second plate area 442A. In an embodiment, in the unfolding state of the electronic device 1, the fourth bending area B24 may be located to be spaced apart from the area between the first concave part \textcircled{1} and the fourth area 704, and the fourth area 704 on the second area 702. In an embodiment, in the unfolding state of the electronic device 1, the fifth bending area B25 may be located to be spaced apart from the area between the second concave part \textcircled{2} and the fifth area 705, and the fifth area 705 on the third area 703. In the unfolding state of the electronic device 1, the first area 701, the second area 702, and the third area 703 that form the recess 301 may reduce the bending stress that exerts an influence on the damage or permanent deformation of the first part 61 by guiding the deformation so that the first bending area B21, the second bending area B22, the third bending area B23, the fourth bending area B24, and the fifth bending area B25 are formed with the threshold curvature radius or the curvature radius that is larger than the threshold curvature radius. The first area 701, the second area 702, and the third area 703 that form the recess 301 may be designed in consideration of various conditions, such as the length, thickness, or yield stress of the first part 61 of the flexible printed circuit board 60, so that the bending stress is not concentrated onto any one bending area, or the bending stress does not reach the yield stress or more. For example, a part of the first area 701 corresponding to the center axis E may include a smooth curved surface so as to reduce the bending stress. Although not illustrated, the first area 701, the second area 702, and the third area 703 that form the recess 301 are not limited to the illustrated example, but may be variously deformed. As another example, a plurality of protrusions may be provided as in the first area 701. As another example, the shape of the first area 701 is not limited to the illustrated convex shape, but other various convex shapes may be formed.

According to an embodiment, the second area 702 and the fourth area 704, and/or the third area 703 and the fifth area 705 may be smoothly connected to each other.

According to an embodiment, the area between the first concave part \textcircled{1} and the fourth area 704 on the second area 702 may include a plane, and in the unfolding state of the electronic device 1, an angle F1 of substantially 90 degrees may be formed with respect to the first support plate 441 (or first plate area 441A). The area between the second concave part \textcircled{2} and the fifth area 705 on the third area 703 may include a plane, and in the unfolding state of the electronic device 1, an angle F2 of substantially 90 degrees may be formed with respect to the second support plate 442 (or second plate area 442A).

According to various embodiments, the area between the first concave part \textcircled{1} and the fourth area 704 on the second area 702 may include a plane, and in the unfolding state of the electronic device 1, an acute angle or an obtuse angle F1 may be formed with respect to the first support plate 441 (or first plate area 441A). The area between the second concave part \textcircled{2} and the fifth area 705 on the third area 703 may include a plane, and in the unfolding state of the electronic device 1, an acute angle or an obtuse angle F2 may be formed with respect to the second support plate 442 (or second plate area 442A). According to various embodiments, the area between the first concave part \textcircled{1} and the fourth area 704 on the second area 702, and/or the area between the second concave part \textcircled{2} and the fifth area 705 on the third area 703 may include curved surfaces.

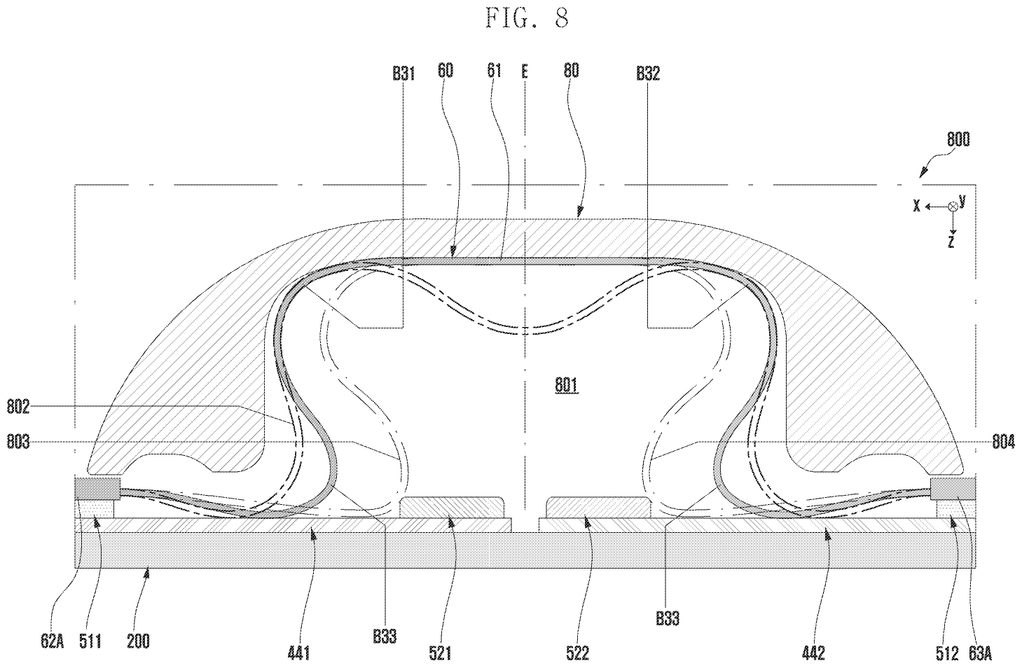

FIG. 8 illustrates a cross-sectional structure for a part of an electronic device in a state where an electronic device according to a second comparative example, being provided with. For example, a hinge housing 80 having a recess 801 that does not include a first area 701 according to an embodiment of the disclosure. The second comparative example is merely presented for comparison with an embodiment of the disclosure, and it is interpreted that it does not have a prior status for an embodiment of the disclosure.

Referring to FIG. 8 depicting cross-sectional structure 800, in the unfolding state of an electronic device according to a second comparative example, the first part 61 of the flexible printed circuit board 60 formed with a length of a designated range may include a first bending area B31, a second bending area B32, a third bending area B33, and a fourth bending area B34. The first bending area B31 and the second bending area B32 may be located in a recess 801. The reference numeral “802” indicates a cross-sectional structure in which the first part 61 of the flexible printed circuit board 60 is disposed in an embodiment of FIG. 5 including the first area 701. In the second comparative example, as compared with an embodiment of FIG. 5 including the first area 701, the third bending area B33 between the first bending area B31 and the first fixing part 62A and the fourth bending area B34 between the second bending area B32 and the second fixing part 63A on the flexible printed circuit board 60 may be formed with a curvature radius that is smaller than the threshold curvature radius, and thus a bending stress that exerts an influence on the damage of the first part 61 may occur. In case of the second comparative example, a yield stress or a bending stress that is greater than the yield stress may occur in the third bending area B33 and/or the fourth bending area B34, and thus the first part 61 may be damaged or permanently deformed. In case of the second comparative example, if the switching of the electronic device between the folding state and the unfolding state is repeated, the bending stress occurring in the third bending area B33 and/or the fourth bending area B34 may cause the damage or the permanent deformation through the deterioration or loss of the elastic force due to fatigue accumulation. In an embodiment of FIG. 5 including the first part 61, it is possible to reduce the bending stress that occurs in the bending areas (e.g., the first bending area B21, the second bending area B22, the third bending area B23, the fourth bending area B24, and the fifth bending area B25 of FIG. 7) of the first part 61 of the flexible printed circuit board in the unfolding state of the electronic device 1. For example, the first part 61 of the flexible printed circuit board 60 may be formed with a length of a value included in the range of about 17 to 19 mm, and in case of the second comparative example, the bending stress of about 43 MPa may occur in the third bending area B33 or the fourth bending area B34. In case of an embodiment of FIG. 5 including the first area 701, the bending stress of about 34 MPa that is smaller than that of the second comparative example may occur in the fourth bending area B24 (refer to FIG. 7) or the fifth bending area B25 (refer to FIG. 7).

According to the embodiment of FIG. 5 including the first area 701, in the unfolding state of the electronic device, the first part 61 may include one of the third bending area indicated by the reference numeral “803” and the fourth bending area indicated by the reference numeral “804”, and thus both sides of the first part 61 are not asymmetrically located about the center axis E.

According to an embodiment of the disclosure, the electronic device (e.g., electronic device 1 of FIG. 1) may include a foldable housing (e.g., foldable housing 10 of FIG. 1). The foldable housing may include a first housing (e.g., first housing 11 of FIG. 1), a second housing (e.g., second housing 12 of FIG. 1), and a folding part between the first housing and the second housing. The electronic device may include a flexible printed circuit board (e.g., flexible printed circuit board 60 of FIG. 5) located in an inner space of the foldable housing. The flexible printed circuit board may include a first part (e.g., first part 61 of FIG. 5) corresponding to the folding part, a second part (e.g., second part 62 of FIG. 5) extending from the first part to the first housing, and a third part (e.g., third part 63 of FIG. 5) extending from the first part to the second housing. The folding part may include at least one hinge (e.g., first hinge 431 and second hinge 432 of FIG. 4) connecting the first housing and the second housing with each other, and a hinge housing (e.g., hinge housing 30 of FIG. 5) configured to cover the at least one hinge. The hinge housing may include a first surface (e.g., first surface 30A of FIG. 6) exposing to an outside in a folding state of the foldable housing (e.g., folding state of the electronic device of FIG. 6) and forming a part of an outer surface of the electronic device. The hinge housing may include a second surface (e.g., second surface 30B of FIG. 6) located on an opposite side to the first surface. On the second surface, a recess (e.g., recess 301 of FIG. 6) corresponding to the first part may be formed. As seen from a cross section of a plane that is vertical to a direction of a folding axis (e.g., folding axis A of FIG. 7) of the folding part, an area forming the recess on the second surface may include a first area (e.g., first area 701 of FIG. 7) aligned with the folding axis and protruding in a first direction toward the folding axis, a second area (e.g., second area 702 of FIG. 7) extending from one end part of the first area, and a third area (e.g., third area 703 of FIG. 7) extending from the other end part of the first area and located on an opposite side to the second area across the first area. Based on a center axis (e.g., center axis E of FIG. 7) that is vertical to the folding axis and passes the folding axis, the recess may include a first concave part (e.g., first concave part \textcircled{1} of FIG. 7) formed on a part of the first area and the second area and carved in a second direction that is opposite to the first direction, and a second concave part (e.g., second concave part \textcircled{2} of FIG. 7) formed on a part of the first area and the third area and carved in the second direction.

According to an embodiment of the disclosure, the first area (e.g., first area 701 of FIG. 7) may include a curved surface having both sides symmetrical about the center axis (e.g., center axis E of FIG. 7) and being convex in the first direction.

According to an embodiment of the disclosure, as seen from the cross section, the recess (recess 301 of FIG. 7) may have both sides symmetrical about the center axis (e.g., center axis E of FIG. 7).

According to an embodiment of the disclosure, the first part (e.g., first part 61 of FIG. 7) may have both sides located symmetrically about the center axis (e.g., center axis E of FIG. 7) as deformation of the first part may be guided by the recess (e.g., recess 301 of FIG. 7) in an unfolding state of the foldable housing.

According to an embodiment of the disclosure, deformation of the first part (e.g., first part 61 of FIG. 7) may be guided by the recess (e.g., recess 301 of FIG. 7) in an unfolding state of the foldable housing. In the unfolding state of the foldable housing, the first part may include a second bending area (e.g., second bending area B22 of FIG. 7) located to correspond to the first concave part (e.g., first concave part \textcircled{1} of FIG. 7). In the unfolding state of the foldable housing, the first part may include a third bending area (e.g., third bending area B23 of FIG. 7) located to correspond to the second concave part (e.g., second concave part \textcircled{2} of FIG. 7). In the unfolding state of the foldable housing, the first part may include a first bending area (e.g., first bending area B21 of FIG. 7) located to correspond to the first area. The first bending area may be bent reversely to the second bending area and the third bending area. In the unfolding state of the foldable housing, the first part may include a fourth bending area (e.g., fourth bending area B24 of FIG. 7) between the second part (e.g., second part 62 of FIG. 5) and the second bending area. The fourth bending area may be bent reversely to the second bending area. In the unfolding state of the foldable housing, the first part may include a fifth bending area (e.g., fifth bending area B25 of FIG. 7) between the third part (e.g., third part 63 of FIG. 5) and the third bending area. The fifth bending area may be bent reversely to the third bending area.

According to an embodiment of the disclosure, the first part (e.g., first part 61 of FIG. 6) may be located separately from the second surface (e.g., second surface 30B of FIG. 6) in the folding state of the foldable housing.

According to an embodiment of the disclosure, as seen from the cross section, the second surface (e.g., second surface 30B of FIG. 7) may include a fourth area (e.g., fourth area 704 of FIG. 7) extending from the second area (e.g., second area 7020 of FIG. 7), and a fifth area (e.g., fifth area 705 of FIG. 7) extending from the third area (e.g., third area 703 of FIG. 7). The first area (e.g., first area 7010 of FIG. 7) may be formed with a height that does not protrude in the first direction with respect to the fourth area and the fifth area.

According to an embodiment of the disclosure, the electronic device may further include a flexible display (e.g., flexible display 20 of FIG. 5) located in the inner space of the foldable housing. The flexible display may include a first display area located to correspond to the first housing (e.g., first housing 11 of FIG. 1), a second display area located to correspond to the second housing, and a third display area (e.g., folding display area 200F of FIG. 5) located to correspond to the folding part and connecting the first display area and the second display area with each other. The electronic device may include a first support structure (e.g., first support structure 411 of FIG. 5) located in an inner space of the first housing. The first support structure may support a part of the first display area. The electronic device may include a second support structure (e.g., second support structure 421 of FIG. 5) located in an inner space of the second housing. The second support structure may support a part of the second display area. The first support structure and the second support structure may be connected by the at least one hinge (e.g., first hinge 431 and second hinge 432 of FIG. 4). The electronic device may include a first support plate (e.g., first support plate 441 of FIG. 5) connected to the first support structure. The first support plate may include a first plate area (e.g., first plate area 441A of FIG. 5) and a third plate area (e.g., third plate area 441B of FIG. 5). The first plate area may include an area configured to support a part of the first display area, and a first end area (e.g., first end area 441C of FIG. 5) configured to support a part of the third display area in an unfolding state of the foldable housing. The third plate area may extend from the first plate area, and may support a part of the first plate area. The third plate area may be connected to the first support structure. The electronic device may include a second support plate (e.g., second support plate 442 of FIG. 5). The second support plate may include a second plate area (e.g., second plate area 442A of FIG. 5) and a fourth plate area (e.g., fourth plate area 442B of FIG. 5). The second plate area may include an area configured to support a part of the second display area, and a second end area (e.g., second end area 442C of FIG. 5) configured to support the part of the third display area in the unfolding state of the foldable housing. The fourth plate area may extend from the second plate area, and may support a part of the second display area. The fourth plate area may be connected to the second support structure. A part (e.g., first fixing part 62A of FIG. 5) of the second part adjacent to the first part may be combined with the second plate area. A part (e.g., second fixing part 63A of FIG. 5) of the third part adjacent to the first part may be combined with the fourth plate area. In the unfolding state of the foldable housing, the first plate area and the second plate area may be located to face the second surface. In the unfolding state of the foldable housing, the first part may be located in a space among the first plate area, the second plate area, and the second surface.

According to an embodiment of the disclosure, in the unfolding state of the foldable housing, the first part (e.g., first part 61 of FIG. 7) may be located in the space by being supported by an area of the second surface (e.g., second surface 30B of FIG. 7) that forms the recess (recess 301 of FIG. 7), the first plate area (e.g., first plate area 441A of FIG. 7), and the second plate area (e.g., second plate area 442A of FIG. 7). In the unfolding state of the foldable housing, the deformation of the first part may be guided by the recess. In the unfolding state of the foldable housing, the first part may include a second bending area (e.g., second bending area B22 of FIG. 7) located to correspond to the first concave part (e.g., first concave part \textcircled{1} of FIG. 7). In the unfolding state of the foldable housing, the first part may include a third bending area (e.g., third bending area B23 of FIG. 7) located to correspond to the second concave part (e.g., second concave part \textcircled{2} of FIG. 7). In the unfolding state of the foldable housing, the first part may include a first bending area (e.g., first bending area B21 of FIG. 7) located to correspond to the first area (e.g., first area 701 of FIG. 7). The first bending area may be bent reversely to the second bending area and the third bending area. In the unfolding state of the foldable housing, the first part may include a fourth bending area (e.g., fourth bending area B24 of FIG. 7) between the second part (second part 62 of FIG. 5) and the second bending area. The fourth bending area B24 may be bent reversely to the second bending area. In the unfolding state of the foldable housing, the first part may include a fifth bending area (e.g., fifth bending area B25 of FIG. 7) between the third parts (e.g., third part 63 of FIG. 5). The fifth bending area B25 may be bent reversely to the third bending area.

According to an embodiment of the disclosure, in the unfolding state of the foldable housing, the fourth bending area (e.g., fourth bending area B24 of FIG. 7) may be located to be spaced apart from an area between the first concave part (e.g., first concave part \textcircled{1} of FIG. 7) and the fourth area (e.g., fourth area 704 of FIG. 7) in the second area (e.g., second area 702 of FIG. 7), and the fourth area. In the unfolding state of the foldable housing, the fifth bending area (e.g., fourth bending area B24 of FIG. 7) may be located to be spaced apart from an area between the second concave part (e.g., second concave part \textcircled{2} of FIG. 7) and the fifth area (e.g., fifth area 705 of FIG. 7) in the third area (e.g., third area 703 of FIG. 7), and the fifth area.

According to an embodiment of the disclosure, in the unfolding state of the foldable housing, the first support plate (e.g., first support plate 441 of FIG. 6) and the second support plate 442 may be spaced apart to overlap each other. In the unfolding state of the foldable housing, the third display area (e.g., folding display area 200F of FIG. 7) may be bent, and may be located between the first end area (e.g., first end area 441C of FIG. 6) and the second end area (e.g., second end area 442C of FIG. 6). The first end area and the second end area may be located out of the recess (e.g., recess 301 of FIG. 6).

According to an embodiment of the disclosure, the first part (e.g., first part 61 of FIG. 6) may be located to be separated from the first end area (e.g., first end area 4441C of FIG. 6) and the second end area (e.g., second end area 442C of FIG. 6) in the folding state of the foldable housing.

According to an embodiment of the disclosure, the electronic device may further include a first buffer member (e.g., first buffer member 521 of FIG. 6) located in the first end area (e.g., first end area 441C of FIG. 6). The electronic device may further include a second buffer member (e.g., second buffer member 522 of FIG. 6) located in the second end area (e.g., second end area 442C of FIG. 6).

According to an embodiment of the disclosure, the at least one hinge (e.g., first hinge 431 of FIG. 4) may include a first hinge (e.g., first hinge 431 of FIG. 4) and a second hinge (e.g., second hinge 432 of FIG. 4). The first support plate (e.g., first support plate 441 of FIG. 4) and the second support plate (e.g., second support plate 442 of FIG. 4) may be located at least partly between the first hinge and the second hinge.

According to an embodiment of the disclosure, the first housing (e.g., first housing 11 of FIG. 1) may include a first cover member (e.g., first cover member 451 of FIG. 5) located to correspond to the hinge housing (e.g., hinge housing 30 of FIG. 5). The second housing (e.g., second housing 12 of FIG. 1) may include a second cover member (e.g., second cover member 452 of FIG. 5) located to correspond to the hinge housing. In the unfolding state of the foldable housing, the first surface (e.g., first surface 30A of FIG. 5) of the hinge housing may be hidden by the first cover member and the second cover member and may not be exposed to the outside. In the folding state of the foldable housing, the first surface of the hinge housing may be exposed to the outside through a gap between the first cover member and the second cover member.

According to an embodiment of the disclosure, an electronic device (e.g., electronic device 1 of FIG. 1) may include a foldable housing (e.g., foldable housing 10 of FIG. 1). The foldable housing may include a first housing (e.g., first housing 11 of FIG. 1), a second housing (e.g., second housing 12 of FIG. 1), and a folding part between the first housing and the second housing. The electronic device may include a flexible printed circuit board (e.g., flexible printed circuit board 60 of FIG. 5) located in an inner space of the foldable housing. The flexible printed circuit board may include a first part (e.g., first part 61 of FIG. 5) corresponding to the folding part, a second part (e.g., second part 62 of FIG. 5) extending from the first part to the first housing, and a third part (e.g., third part 63 of FIG. 5). The electronic device may include a flexible display (e.g., flexible display 20 of FIG. 5) located in an inner space of the foldable housing. The flexible display may include a first display area located to correspond to the first housing, a second display area located to correspond to the second housing, and a third display area (e.g., folding display area 200F of FIG. 5) located to correspond to the folding part and connecting the first display area and the second display area with each other. The electronic device may include a first support structure (e.g., first support structure 411 of FIG. 5). The first support structure may support a part of the first display area. The electronic device may include a second support structure (e.g., second support structure 421 of FIG. 5) located in an inner space of the second housing. The second support structure may support a part of the second display area. The electronic device may include a first support plate (e.g., first support plate 441 of FIG. 5) connected to the first support structure. The first support plate may include a first plate area (first plate area 441A of FIG. 5) and a third plate area (e.g., third plate area 441B of FIG. 5). The first plate area may include a part of the first display area, and a first end area (e.g., first end area 441C of FIG. 5) configured to support a part of the third display area in an unfolding state of the foldable housing. The third plate area may extend from the first plate area, support a part of the first plate area, and be connected to the first support structure. The electronic device may include a second support plate (e.g., second support plate 442 of FIG. 5) connected to the second support structure. The second support plate may include a second plate area (e.g., second plate area 442A of FIG. 5) and a fourth plate area (e.g., fourth plate area 442B of FIG. 5). The second plate area may include a part of the second display area and a second end area (e.g., second end area 442C of FIG. 5) configured to support the part of the third display area in the unfolding state of the foldable housing. The fourth plate area may extend from the second plate area, support a part of the second display area, and be connected to the second support structure. A part (e.g., first fixing part 62A of FIG. 5) of the second part adjacent to the first part may be combined with the second plate area. A part (e.g., second fixing part 63A of FIG. 5) of the third part adjacent to the first part may be combined with the fourth plate area. In the unfolding state of the foldable housing, the first plate area and the second plate area may be located to face the second surface, and the first part may be located in a space among the first plate area, the second plate area, and the second surface. The folding part may include at least one hinge (e.g., first hinge 431 and second hinge 432 of FIG. 4) connecting the first support structure and the second support structure with each other. The folding part may include a hinge housing (e.g., hinge housing 30 of FIG. 5) configured to cover the at least one hinge. The hinge housing may include a first surface (e.g., first surface 30A of FIG. 5) exposing to an outside in a folding state of the foldable housing and forming a part of an outer surface of the electronic device. The hinge housing may include a second surface (e.g., second surface 30B of FIG. 5) located on an opposite side to the first surface. On the second surface, a recess (e.g., recess 301 of FIG. 5) corresponding to the first part may be formed. As seen from a cross section of a plane that is vertical to a direction of a folding axis (e.g., folding axis A of FIG. 7) of the folding part, an area forming the recess on the second surface may include a first area (e.g., first area 701 of FIG. 7) aligned with the folding axis and protruding in a first direction toward the folding axis, a second area (e.g., second area 702 of FIG. 7) extending from one end part of the first area, and a third area (e.g., third area 703 of FIG. 7) extending from the other end part of the first area and located on an opposite side to the second area across the first area. Based on a center axis that is vertical to the folding axis and passes the folding axis, the recess may include a first concave part (e.g., first concave part \textcircled{1} of FIG. 7) formed on a part of the first area and the second area and carved in a second direction that is opposite to the first direction, and a second concave part (e.g., second concave part \textcircled{2} of FIG. 7) formed on a part of the first area and the third area and carved in the second direction. As seen from the cross section, the recess may have both sides symmetrical about the center axis.

According to an embodiment of the disclosure, in the unfolding state of the foldable housing, the first part (e.g., first part 61 of FIG. 7) is located in the space by being supported by an area of the second surface (second surface 30B of FIG. 7) forming the recess, the first plate area (e.g., first plate area 441A of FIG. 7), and the second plate area (e.g., second plate area 442A of FIG. 7). In the unfolding state of the foldable housing, deformation of the first part is guided by the recess, and both sides of the first part are symmetrically located about the center axis. In the unfolding state of the foldable housing, the first part may include a second bending area (e.g., second bending area B22) located to correspond to the first concave part (e.g., first concave part \textcircled{1} of FIG. 7). In the unfolding state of the foldable housing, the first part may include a third bending area (e.g., third bending area B23 of FIG. 7) located to correspond to the second concave part (e.g., second concave part \textcircled{2} of FIG. 7). In the unfolding state of the foldable housing, the first part may include a first bending area (e.g., first bending area B21 of FIG. 7) located to correspond to the first area. In the unfolding state of the foldable housing, the first bending area may be bent reversely to the second bending area and the third bending area. In the unfolding state of the foldable housing, the first part may include a fourth bending area (e.g., fourth bending areas B24 of FIG. 7) between the second part (e.g., second part 62 of FIG. 5) and the second bending area. The fourth bending part may be bent reversely to the second bending area. In the unfolding state of the foldable housing, the first part may include a fifth bending area (e.g., fifth bending area B25 of FIG. 7) between the third part (e.g., third part 63 of FIG. 5) and the third bending area. The fifth bending area may be bent reversely to the third bending area.

According to an embodiment of the disclosure, the first part (e.g., first part 61 of FIG. 6) may be located separately from the second surface (e.g., second surface 30B of FIG. 6) in the folding state of the foldable housing.

According to an embodiment of the disclosure, as seen from the cross section, the second surface (e.g., second surface 30B of FIG. 7) may include a fourth area (e.g., fourth area 704 of FIG. 7) extending from the second area (e.g., second area 7020 of FIG. 7), and a fifth area (e.g., fifth area 705 of FIG. 7) extending from the third area (e.g., third area 703 of FIG. 7). The first area (e.g., first area 7010 of FIG. 7) may be formed with a height that does not protrude in the first direction with respect to the fourth area and the fifth area.

According to an embodiment of the disclosure, in the folding state of the foldable housing, the first support plate (e.g., first support plate 441 of FIG. 6) and the second support plate 442 may be separated to overlap each other. in the folding state of the foldable housing, the third display area (e.g., folding display area 200F of FIG. 7) may be bent, and may be located between the first end area (e.g., first end area 441C of FIG. 6) and the second end area (e.g., second end area 442C of FIG. 6). The first end area and the second end area may be located out of the recess (e.g., recess 301 of FIG. 6). The first part (e.g., first part 61 of FIG. 6) may be located to be separated from the first end area and the second end area.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a foldable housing including:
a first housing,
a second housing, and
a folding part between the first housing and the second housing; and
a flexible printed circuit board located in an inner space of the foldable housing,
wherein the flexible printed circuit board includes:
a first part corresponding to the folding part,
a second part extending from the first part to the first housing, and
a third part extending from the first part to the second housing,
wherein the folding part includes:
at least one hinge connecting the first housing and the second housing with each other, and
a hinge housing configured to cover the at least one hinge,
wherein the hinge housing includes:
a first surface exposing to an outside in a folding state of the foldable housing and forming a part of an outer surface of the electronic device, and
a second surface located on an opposite side to the first surface and formed with a recess corresponding to the first part,
wherein as seen from a cross section of a plane that is vertical to a direction of a folding axis of the folding part, an area forming the recess on the second surface includes:
a first area aligned with the folding axis and protruding in a first direction toward the folding axis,
a second area extending from one end part of the first area, and
a third area extending from another end part of the first area and located on an opposite side to the second area across the first area, and
wherein based on a center axis that is vertical to the folding axis and passes the folding axis, the recess includes:
a first concave part formed on a part of the first area and the second area and carved in a second direction that is opposite to the first direction, and
a second concave part formed on a part of the first area and the third area and carved in the second direction.

2. The electronic device of claim 1, wherein the first area comprises a curved surface having both sides symmetrical about the center axis and being convex in the first direction.

3. The electronic device of claim 1, wherein as seen from the cross section, the recess has both sides symmetrical about the center axis.

4. The electronic device of claim 1, wherein the first part has both sides located symmetrically about the center axis as deformation of the first part is guided by the recess in an unfolding state of the foldable housing.

5. The electronic device of claim 1,
wherein deformation of the first part is guided by the recess in an unfolding state of the foldable housing, and
wherein the first part comprises:
a second bending area located to correspond to the first concave part,
a third bending area located to correspond to the second concave part,
a first bending area located to correspond to the first area, and bent reversely to the second bending area and the third bending area,
a fourth bending area between the second part and the second bending area, being bent reversely to the second bending area, and
a fifth bending area between the third part and the third bending area, being bent reversely to the third bending area.

6. The electronic device of claim 5, wherein the first part is located separately from the second surface in the folding state of the foldable housing.

7. The electronic device of claim 1,
wherein as seen from the cross section, the second surface comprises:
a fourth area extending from the second area, and
a fifth area extending from the third area, and
wherein the first area is formed with a height that does not protrude in the first direction with respect to the fourth area and the fifth area.

8. The electronic device of claim 7, further comprising:
a flexible display located in the inner space of the foldable housing and including:
a first display area located to correspond to the first housing,
a second display area located to correspond to the second housing, and
a third display area located to correspond to the folding part and connecting the first display area and the second display area with each other;
a first support structure located in an inner space of the first housing and configured to support a part of the first display area;
a second support structure located in an inner space of the second housing, configured to support a part of the second display area, and connected to the first support structure by the at least one hinge;
a first support plate connected to the first support structure and including:
a first plate area including:
an area configured to support a part of the first display area, and
a first end area configured to support a part of the third display area in an unfolding state of the foldable housing, and
a first support plate extending from the first plate area, configured to support a part of the first plate area, and including a third plate area connected to the first support structure; and
a second support plate connected to the second support structure and including:
a second plate area including:
an area configured to support a part of the second display area, and
a second end area configured to support the part of the third display area in the unfolding state of the foldable housing, and
a second support plate extending from the second plate area, configured to support a part of the second display area, and including a fourth plate area connected to the second support structure,
wherein a part of the second part adjacent to the first part is combined with the second plate area, and a part of the third part adjacent to the first part is combined with the fourth plate area, and
wherein in the unfolding state of the foldable housing, the first plate area and the second plate area are located to face the second surface, and the first part is located in a space among the first plate area, the second plate area, and the second surface.

9. The electronic device of claim 8,
wherein in the unfolding state of the foldable housing, the first part is located in the space by being supported by an area of the second surface forming the recess, the first plate area, and the second plate area,
wherein deformation of the first part is guided by the recess, and
wherein the first part comprises:
a second bending area located to correspond to the first concave part,
a third bending area located to correspond to the second concave part,
a first bending area located to correspond to the first area, and bent reversely to the second bending area and the third bending area,
a fourth bending area between the second part and the second bending area, being bent reversely to the second bending area, and
a fifth bending area between the third part and the third bending area, being bent reversely to the third bending area.

10. The electronic device of claim 9,
wherein in the unfolding state of the foldable housing, the fourth bending area is located to be spaced apart from an area between the first concave part and the fourth area in the second area, and the fourth area, and
wherein the fifth bending area is located to be spaced apart from an area between the second concave part and the fifth area in the third area, and the fifth area.

11. The electronic device of claim 8,
wherein in the folding state of the foldable housing, the first support plate and the second support plate are spaced apart to overlap each other,
wherein the third display area is bent, and is located between the first end area and the second end area, and
wherein the first end area and the second end area are located out of the recess.

12. The electronic device of claim 8, wherein the first part is located to be spaced apart from the first end area and the second end area in the folding state of the foldable housing.

13. The electronic device of claim 8, further comprising:
a first buffer member located in the first end area; and
a second buffer member located in the second end area.

14. The electronic device of claim 8,
wherein the at least one hinge comprises a first hinge and a second hinge, and
wherein the first support plate and the second support plate are located at least partly between the first hinge and the second hinge.

15. The electronic device of claim 1,
wherein the first housing includes a first cover member located to correspond to the hinge housing,
wherein the second housing includes a second cover member located to correspond to the hinge housing,
wherein in an unfolding state of the foldable housing, the first surface of the hinge housing is hidden by the first cover member and the second cover member and is not exposed to the outside, and
wherein in the folding state of the foldable housing, the first surface of the hinge housing is exposed to the outside through a gap between the first cover member and the second cover member.

16. An electronic device comprising:
a foldable housing including:
a first housing,
a second housing, and
a folding part between the first housing and the second housing;
a flexible printed circuit board located in an inner space of the foldable housing, and including:
a first part corresponding to the folding part,
a second part extending from the first part to the first housing, and
a third part extending from the first part to the second housing;
a flexible display located in the inner space of the foldable housing and including:
a first display area located to correspond to the first housing,
a second display area located to correspond to the second housing, and
a third display area located to correspond to the folding part and connecting the first display area and the second display area with each other;
a first support structure located in an inner space of the first housing and configured to support a part of the first display area;
a second support structure located in an inner space of the second housing and configured to support a part of the second display area;
a first support plate connected to the first support structure and including:
a first plate area including:
an area configured to support a part of the first display area, and
a first end area configured to support a part of the third display area in an unfolding state of the foldable housing, and
a first support plate extending from the first plate area, configured to support a part of the first plate area, and including a third plate area connected to the first support structure; and
a second support plate connected to the second support structure and including:
a second plate area including:
an area configured to support a part of the second display area, and
a second end area configured to support the part of the third display area in the unfolding state of the foldable housing, and
a second support plate extending from the second plate area, configured to support a part of the second display area, and including a fourth plate area connected to the second support structure,
wherein a part of the second part adjacent to the first part is combined with the second plate area, and a part of the third part adjacent to the first part is combined with the fourth plate area,
wherein the folding part includes:
at least one hinge connecting the first support structure and the second support structure with each other, and
a hinge housing configured to cover the at least one hinge,
wherein the hinge housing includes:
a first surface exposing to an outside in a folding state of the foldable housing and forming a part of an outer surface of the electronic device, and
a second surface located on an opposite side to the first surface and formed with a recess corresponding to the first part,
wherein in the unfolding state of the foldable housing, the first plate area and the second plate area are located to face the second surface, and the first part is located in a space among the first plate area, the second plate area, and the second surface,
wherein as seen from a cross section of a plane that is vertical to a direction of a folding axis of the folding part, an area forming the recess on the second surface includes:
a first area aligned with the folding axis and protruding in a first direction toward the folding axis,
a second area extending from one end part of the first area, and
a third area extending from another end part of the first area and located on an opposite side to the second area across the first area,
wherein based on a center axis that is vertical to the folding axis and passes the folding axis, the recess includes:
a first concave part formed on a part of the first area and the second area and carved in a second direction that is opposite to the first direction, and
a second concave part formed on a part of the first area and the third area and carved in the second direction, and
wherein as seen from the cross section, the recess has both sides symmetrical about the center axis.

17. The electronic device of claim 16,
wherein in the unfolding state of the foldable housing, the first part is located in the space by being supported by an area of the second surface forming the recess, the first plate area, and the second plate area,
wherein deformation of the first part is guided by the recess, and both sides of the first part are symmetrically located about the center axis, and
wherein the first part comprises:
a second bending area located to correspond to the first concave part,
a third bending area located to correspond to the second concave part,
a first bending area located to correspond to the first area, and bent reversely to the second bending area and the third bending area,
a fourth bending area between the second part and the second bending area, being bent reversely to the second bending area, and
a fifth bending area between the third part and the third bending area, being bent reversely to the third bending area.

18. The electronic device of claim 16, wherein the first part is located separately from the second surface in the folding state of the foldable housing.

19. The electronic device of claim 16,
wherein as seen from the cross section, the second surface comprises:
a fourth area extending from the second area, and
a fifth area extending from the third area, and
wherein the first area is formed with a height that does not protrude in the first direction with respect to the fourth area and the fifth area.

20. The electronic device of claim 16,
wherein in the folding state of the foldable housing, the first support plate and the second support plate are separated to overlap each other,
wherein the third display area is bent, and is located between the first end area and the second end area,
wherein the first end area and the second end area are located out of the recess, and
wherein the first part is located to be spaced apart from the first end area and the second end area.
